(19) United States
(12) Patent Application Publication
(10) Pub. No.: US 2025/0341754 A1
(43) Pub. Date: Nov. 6, 2025

(54) OPTICAL DIGITAL-TO-ANALOG CONVERTER

(71) Applicant: Taiwan Semiconductor Manufacturing Company, Ltd., Hsinchu (TW)

(72) Inventors: Ming Yang Jung, Kaohsiung City (TW); Chewn-Pu Jou, Hsinchu (TW); Lan-Chou Cho, Hsinchu City (TW); Stefan Rusu, Sunnyvale, CA (US); Cheng-Tse Tang, Hsinchu County (TW); Tai-Chun Huang, New Taipei City (TW); You-Cheng Lu, Tainan City (TW)

(21) Appl. No.: 19/271,882

(22) Filed: Jul. 17, 2025

Related U.S. Application Data
(63) Continuation of application No. 18/302,972, filed on Apr. 19, 2023.
(60) Provisional application No. 63/480,351, filed on Jan. 18, 2023.

(51) Int. Cl. G02F 7/00; G02F 1/21; G02F 1/225; H03M 7/00

(52) U.S. Cl. CPC G02F 7/00; G02F 1/212; G02F 1/2257; H03M 7/008; G02F 2203/50

(57) ABSTRACT

The present disclosure relates to an optical digital-to-analog converter (DAC). The optical DAC includes a first waveguide path configured to receive a first optical signal and a second waveguide path configured to receive a second optical signal. A first phase shifter segment interfaces with the first and second waveguide paths. The first phase shifter segment is configured to selectively generate a first phase shift between the first optical signal and the second optical signal in response to a first digital input. A second phase shifter segment interfaces with the first and second waveguide paths. The second phase shifter segment is configured to selectively generate a second phase shift between the first optical signal and the second optical signal in response to a second digital input. The first digital input and the second digital input correspond to different bits of a digital signal.

### REFERENCE TO RELATED APPLICATIONS

This Application is a Continuation of U.S. application Ser. No. 18/302,972, filed on Apr. 19, 2023, which claims the benefit of U.S. Provisional Application No. 63/480,351, filed on Jan. 18, 2023. The contents of the above-referenced Patent Applications are hereby incorporated by reference in their entirety.

### BACKGROUND

A Mach-Zehnder modulator (MZM) is an interferometric structure that uses constructive and/or destructive interference to modulate an electromagnetic wave (e.g., light). A typical MZM is configured to split an optical input signal into two beams that travel along two different paths. A phase shift may be selectively introduced into a beam extending along one of the paths. The two beams are subsequently merged to form an optical output signal. By controlling a value of phase shift, interference between the two beams can be controlled to modulate an amplitude of the optical output signal.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram showing some embodiments of an optical digital-to-analog converter (DAC) comprising a Mach-Zehnder modulator (MZM).

FIG. 2 illustrates a top-view of some embodiments of a 2-bit optical DAC comprising an MZM.

FIGS. 3A-3D illustrate some embodiments showing operation of a 2-bit optical DAC comprising a MZM in response to different digital input signals.

FIG. 3E illustrates a graph showing some embodiments of different optical output signals generated by the 2-bit optical DAC in response to the different digital input signals of FIGS. 3A-3D.

FIG. 3F illustrates a graph showing some embodiments of discrete optical output powers of the different optical output signals of FIG. 3E.

FIGS. 4A-4D illustrate some additional embodiments of an optical DAC comprising an MZM.

FIG. 5A illustrates a top-view of some embodiments of a 4-bit optical DAC comprising an MZM.

FIG. 5B illustrates a graph showing some embodiments of discrete optical output powers generated by the 4-bit optical DAC of FIG. 5A in response to different digital input signals.

FIG. 6 illustrates a top-view of some alternative embodiments of a 4-bit optical DAC comprising an MZM.

FIG. 7 illustrates a top-view of some embodiments of an n-bit optical DAC comprising an MZM.

FIG. 8A illustrates a graph showing some embodiments of optical output powers generated by an optical DAC with fabrication process variations in response to different digital input signals.

FIGS. 8B-8C illustrate some embodiments of an optical DAC comprising a MZM and a temperature adjustment element configured to mitigate variations in optical output powers due to fabrication process variations.

FIG. 8D illustrates a graph showing some embodiments of optical output powers generated by the optical DAC of FIGS. 8B-8C.

FIGS. 9A-9E illustrate some additional embodiments of disclosed optical DACs comprising an MZM.

FIGS. 10A-19B illustrate some embodiments of a method of forming an integrated chip structure including an optical DAC comprising an MZM.

FIG. 20 illustrates a flow diagram of some embodiments of a method of forming an integrated chip structure including an optical DAC comprising an MZM.

FIG. 21 illustrates a flow diagram of some additional embodiments of a method of forming an integrated chip structure including an optical DAC comprising an MZM.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As integrated chips continue to decrease in size, limitations in processing capabilities and in fundamental material characteristics have made scaling of integrated chip components increasingly difficult (e.g., due to leakage currents, process variations, etc.). Photonic chips (e.g., integrated chips that use light to transmit information) are one potential next generation technology that may enable the semiconductor industry to continue to improve integrated chip performance over traditional integrated chips (e.g., since photons can provide a higher bandwidth than electrons used in conventional integrated chips).

In recent years, silicon photonics has made tremendous progress in many applications including communication, information processing, optical computing, etc. Optical computing systems use light waves (e.g., produced by lasers or incoherent light sources) for data processing, data storage, and/or data communication. Typically, optical computing systems use a digital-to-analog converter (DAC) to convert a digital signal represented by a binary code (e.g., a combination of bits having values of ‘0’ or ‘1’) into an analog signal that can interface with other electronic devices. However, many optical computing systems still utilize electronic DAC.

The present disclosure relates to an optical digital-to-analog converter (DAC), comprising a Mach-Zehnder modulator (MZM), which is configured to modulate an optical input signal based upon a digital signal to generate an analog optical output signal. In some embodiments, the optical DAC comprises a first waveguide path and a second waveguide path configured to respectively receive first and second optical signals from a beam splitter. A first phase shifter segment has a first pair of p-n junctions respectively in communication with one of the first and second waveguide paths. A second phase shifter segment has a second pair of p-n junctions respectively in communication with one of the first and second waveguide paths. The first pair of p-n junctions span different lengths than the second pair of p-n junctions. The first phase shifter segment and/or the second phase shifter segment are configured to selectively introduce phase shifts into the first and second waveguide paths by selectively biasing the p-n junctions based upon values of a digital signal. Because the first and second phase shifter segment have p-n junctions with different lengths, the first and second phase shifter segments will introduce different phase shift values between the first and second optical signals, thereby enabling the optical DAC to generate an analog optical output signal at a plurality of different and discrete optical output powers that respectively correspond to values of the digital signal.

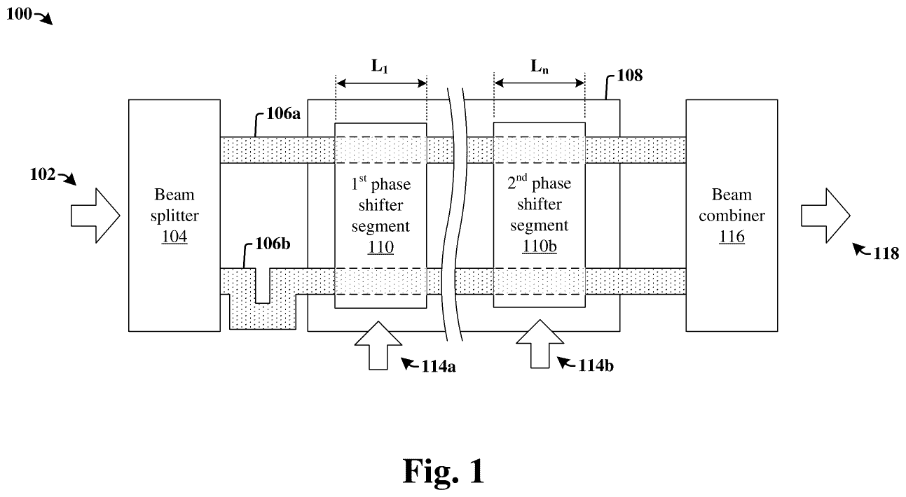

FIG. 1 illustrates a block diagram showing some embodiments of an optical digital-to-analog converter (DAC) 100 comprising a Mach-Zehnder modulator (MZM).

The optical DAC 100 comprises a beam splitter 104 configured to receive an optical input signal 102. The beam splitter 104 is configured to split the optical input signal 102 into a first optical signal that is provided to a first waveguide path 106a and a second optical signal that is provided to a second waveguide path 106b. In some embodiments, the first waveguide path 106a has a first path length and the second waveguide path 106b has a second path length that is different than (e.g., longer than) the first path length. In some embodiments, the first optical signal and the second optical signal may have a same phase and amplitude when output from the beam splitter 104.

The first waveguide path 106a and the second waveguide path 106b are configured to travel through a Mach-Zehnder modulator (MZM) 108 having a plurality of phase shifter segments 110a-110b. The plurality of phase shifter segments 110a-110b are configured to selectively introduce a phase shift between the first optical signal and the second optical signal based upon one or more digital inputs 114a-114b (e.g., respectively comprising one or more values of ‘0’ and ‘1’ corresponding to different bits of a digital signal). A beam combiner 116 is disposed downstream of the MZM 108. The beam combiner 116 is configured to combine the first optical signal and the second optical signal to generate an optical output signal 118.

In some embodiments, the MZM 108 has a first phase shifter segment 110a and a second phase shifter segment 110b located downstream of the first phase shifter segment 110a. The first phase shifter segment 110a comprises first p-n junctions spanning a first length L₁. The second phase shifter segment 110b comprises second p-n junctions spanning a second length L₂ that is different than the first length L₁. The first waveguide path 106a and the second waveguide path 106b are configured to travel through the first p-n junctions within the first phase shifter segment 110, so that the first p-n junctions are in communication with the first waveguide path 106a and the second waveguide path 106b. The first waveguide path 106a and the second waveguide path 106b are also configured to travel through the second p-n junctions within the second phase shifter segment 110b, so that the second p-n junctions are also in communication with the first waveguide path 106a and the second waveguide path 106b.

During operation, the first phase shifter segment 110a is configured to receive a first digital input 114a. Based upon a value(s) of the first digital input 114a, a bias voltage may be applied to one or more of the first p-n junctions. The bias voltage changes a reflective index of the first phase shifter segment 110a, so that the first phase shifter segment 110a selectively introduces a first phase shift between the first optical signal within the first waveguide path 106a and the second optical signal within the second waveguide path 106b. The second phase shifter segment 110b is also configured to receive a second digital input 114b. Based upon a value(s) of the second digital input 114b, the second phase shifter segment 110b is configured to selectively introduce the second phase shift between the first optical signal within the first waveguide path 106a and the second optical signal within the second waveguide path 106b.

Therefore, depending upon values of the one or more digital inputs 114a-114b, the MZM 108 will introduce different phase shifts between the first optical signal within the first waveguide path 106a and the second optical signal within the second waveguide path 106b. The collective effect of the different phase shifts allow the MZM 108 to generate one or more optical output signals having a plurality of different and discrete optical output powers that respectively correspond to values of a digital signal. For example, the collective effect of the first phase shift and the second phase shift can cause a 2-bit optical DAC to generate an output signal having four different output power values. Therefore, by driving the plurality of phase shifter segments 110a-110b to introduce different phase shifts between different waveguide paths, the disclosed optical DAC 100 is able to convert a digital signal into an analog output signal. The optical DAC 100 may be used in a variety of photonic applications. For example, the optical DAC 100 may be used in optical computing systems to enable efficient and high performance optical computing.

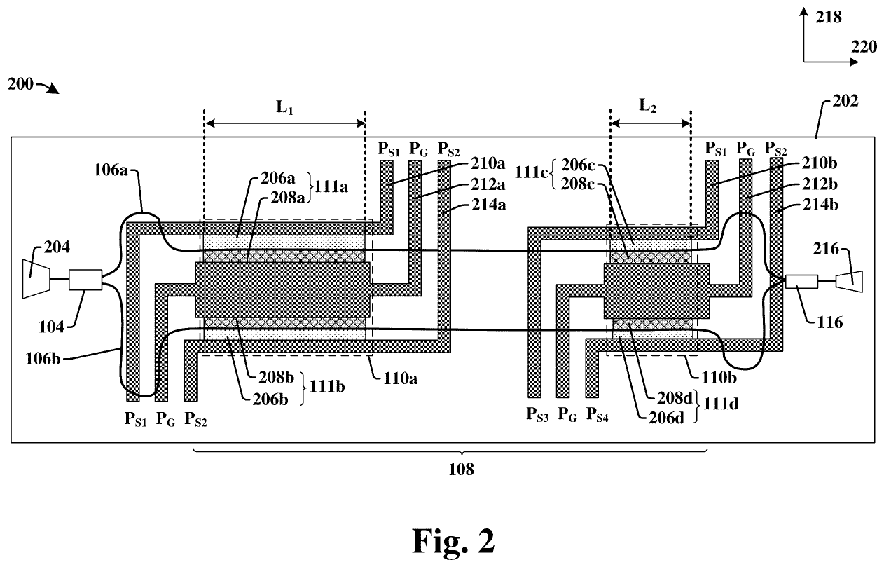

FIG. 2 illustrates a top-view of some embodiments of an optical DAC 200 comprising an MZM.

The optical DAC 200 comprises an input conduit 204 disposed on and/or within a substrate 202. The input conduit 204 is configured to receive an optical input signal. In some embodiments, the input conduit 204 may comprise a grating coupler configured to receive the optical input signal from a fiber optic input channel (e.g., a fiber optic waveguide). In some embodiments, the grating coupler may comprise a tapered structure having a plurality of cavities arranged in a periodic pattern. The input conduit 204 is coupled to a beam splitter 104 that is configured to split the optical input signal into a first optical signal that is provided to a first waveguide path 106a and a second optical signal that is provided to a second waveguide path 106b.

The first waveguide path 106a extends through an MZM 108 having a first phase shifter segment 110a and a second phase shifter segment 110b. The second waveguide path 106b also extends through the first phase shifter segment 110a and the second phase shifter segment 110b. In some embodiments, the first waveguide path 106a has a first path length and the second waveguide path 106b has a second path length that is different than (e.g., longer than) the first path length. In some embodiments, a difference between the first path length and the second path length may be in a range of between approximately 1 micron and approximately 10 millimeters, between approximately 5 microns and approximately 5 millimeters, or other similar values. In some embodiments, a difference between the first path length and the second path length may enable a phase difference between the first optical signal and the second optical signal that is in a range of between approximately 0 and approximately 271 (e.g., between approximately 0° and approximately 360°).

The first phase shifter segment 110a comprises a first phase shifter 111a and a second phase shifter 111b. The first phase shifter 111a comprises a first doped region 206a and a second doped region 208a. The second phase shifter 111b comprises a third doped region 206b and a fourth doped region 208b. The first doped region 206a and the third doped region 206b have a first doping type (e.g., p-type doping). The second doped region 208a and the fourth doped region 208b have a second doping type (e.g., n-type doping) that is different than the first doping type. The first doped region 206a contacts the second doped region 208a along a first p-n junction extending over a first length L₁. The third doped region 206b contacts the fourth doped region 208b along a second p-n junction extending over the first length L₁.

The second phase shifter segment 110b comprises a third phase shifter 111c and a fourth phase shifter 111d. The third phase shifter 111c comprises a fifth doped region 206c and a sixth doped region 208c. The fourth phase shifter 111d comprises a seventh doped region 206d and an eighth doped region 208d. The fifth doped region 206c and the seventh doped region 206d have the first doping type (e.g., p-type doping). The sixth doped region 208c and the eighth doped region 208d have the second doping type (e.g., n-type doping). The fifth doped region 206c contacts the sixth doped region 208c along a third p-n junction extending over a second length L₂. The seventh doped region 206d contacts the eighth doped region 208d along a fourth p-n junction extending over the second length L₂.

In some embodiments, the first p-n junction is separated from the second p-n junction along a first direction 218 and the third p-n junction is separated from the fourth p-n junction along the first direction 218. In some embodiments, the first phase shifter segment 110a is separated from the second phase shifter segment 110b along a second direction 220 that is perpendicular to the first direction 218. In some embodiments, the first length L₁ and the second length L₂ are measured along the second direction 220.

The first length L₁ and the second length L₂ are different, so that the first phase shifter segment 110a and the second phase shifter segment 110b are able to introduce different phase shifts between the first waveguide path 106a and the second waveguide path 106b. The different phase shifts allow the MZM 108 to generate an optical output signal having different and discrete output power levels in response to digital inputs corresponding to different digital signals. In some embodiments, a ratio of the first length L₁ to the second length L₂ may be approximately equal to 2:1. Having a ratio of approximately 2:1 allows for the first phase shifter segment 110a and the second phase shifter segment 110b to introduce phases that will provide for a substantially equal difference between optical output powers corresponding to the different digital signals. In other words, by having a ratio of approximately 2:1 a difference in optical output powers between a first digital signal (e.g., (0,0)) and a second digital signal (e.g., (0,1)) may be approximately equal to a difference in optical output powers between the second digital signal (e.g., (0,1)) and a third digital signal (e.g., (1,0)).

A plurality of interconnect structures 210a-214b are configured to couple signal pads P_{S1}-P_{S4} and ground pads PG to the plurality of phase shifters 111a-111d. For example, a first interconnect structure 210a is configured to couple the first doped region 206a of the first phase shifter 111a to a first signal pad Psi. A second interconnect structure 212a is configured to couple the second doped region 208a of the first phase shifter 111a and the fourth doped region 208b of the second phase shifter 111b to a ground pad PG. A third interconnect structure 214a is configured to couple the third doped region 206b of the second phase shifter 111b to a second signal pad P_{S2}. A fourth interconnect structure 210b is configured to couple the fifth doped region 206c of the third phase shifter 111c to a third signal pad P_{S3}. A fifth interconnect structure 212b is configured to couple the sixth doped region 208c of the third phase shifter 111c and the eighth doped region 208d of the fourth phase shifter 111d to a ground pad PG. A sixth interconnect structure 214b is configured to couple the seventh doped region 206d of the fourth phase shifter 111d to a fourth signal pad P_{S4}. During operation, the plurality of interconnect structures 210a-214b are configured to provide the plurality of phase shifters 111a-111d with one or more digital inputs corresponding to a digital signal. Depending upon a value of the digital inputs, the plurality of phase shifters 111a-111d will collectively introduce different phase shifts between a first optical signal within the first waveguide path 106a and a second optical signal within the second waveguide path 106b.

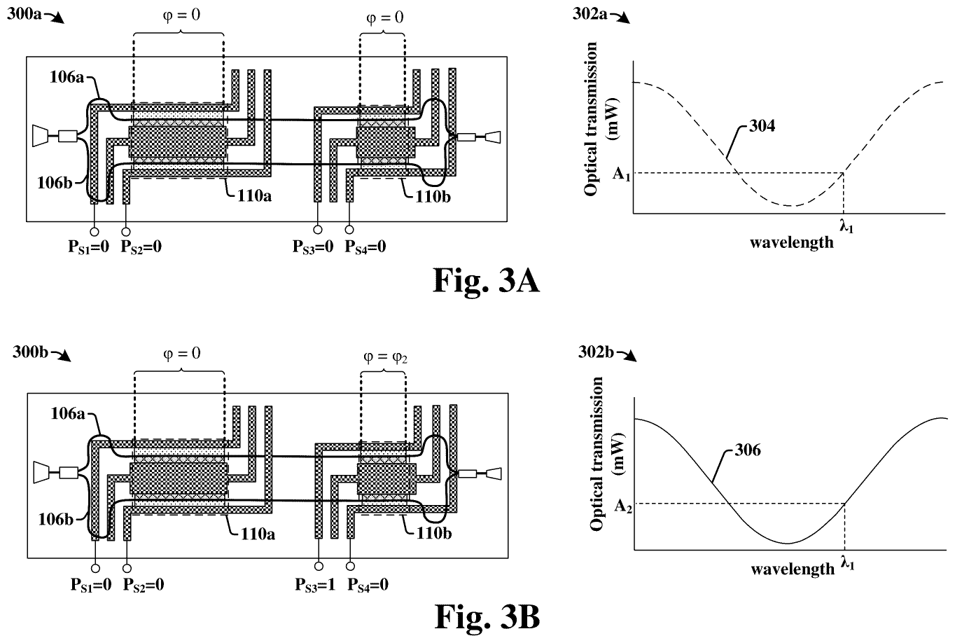

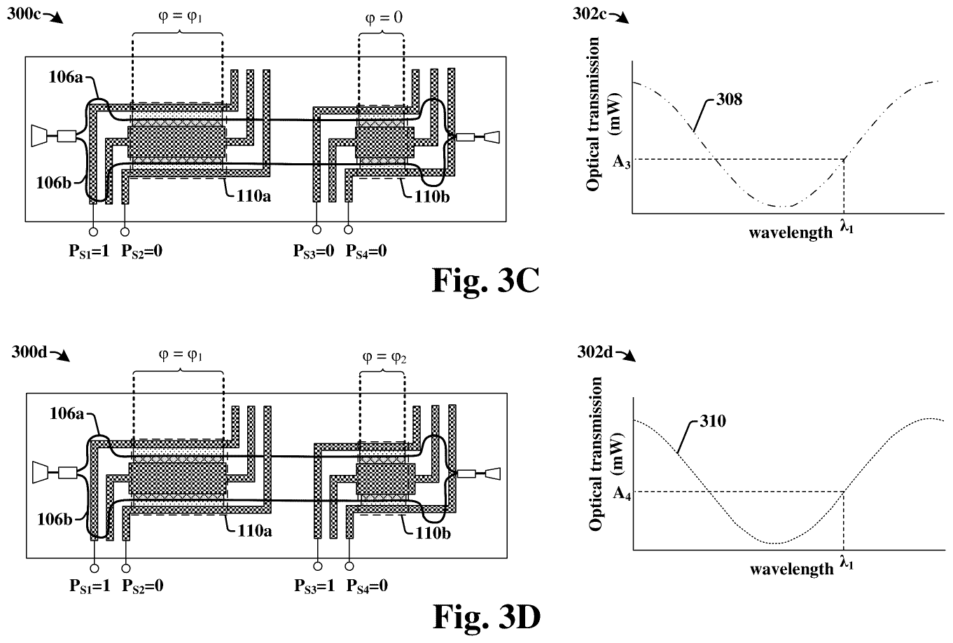

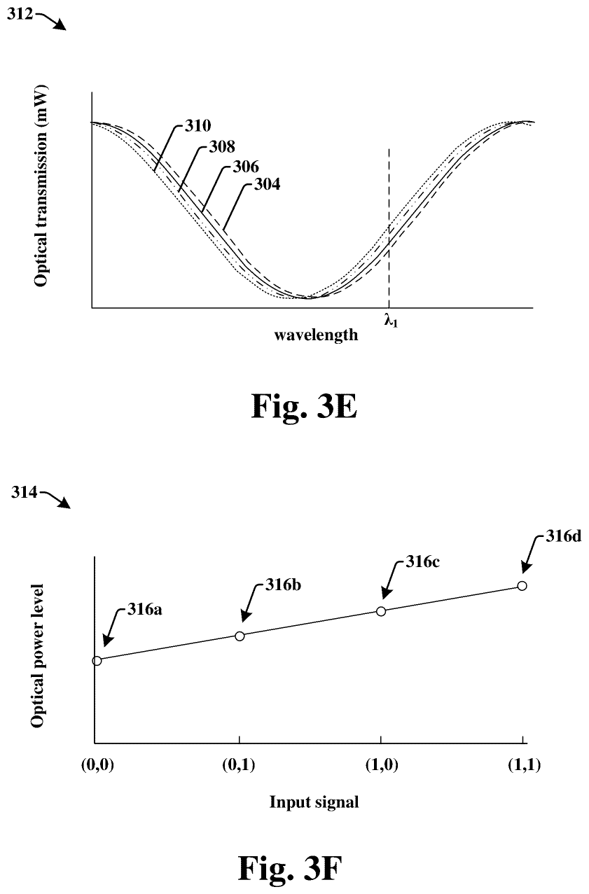

FIGS. 3A-3D illustrate some embodiments of an operation of a 2-bit optical DAC comprising a MZM in response to different digital input signals.

As shown in top-view 300a of FIG. 3A, digital inputs having a value of 0 are provided to a first signal pad P_{S1} and a second signal pad P_{S2} of a first phase shifter segment 110a. Digital inputs having a value of 0 are also provided to a third signal pad P_{S3} and a fourth signal pad P_{S4} of a second phase shifter segment 110b. The digital inputs cause neither the first phase shifter segment 110a nor the second phase shifter segment 110b to introduce a phase shift between the first waveguide path 106a and the second waveguide path 106b. Therefore, a cumulative phase shift between the first phase shifter segment 110a and the second phase shifter segment 110b is equal to a base phase shift φ_{B} caused by a path length difference, giving the optical output signal a first amplitude at a wavelength λ₁. Graph 302a shows an example of curve 304 corresponding to an optical output power (shown on y-axis) of the optical output signal over a range of wavelengths (shown on x-axis).

As shown in top-view 300b of FIG. 3B, a digital input having a value of 0 is provided to the first signal pad Psi, a digital input having a value of 0 is provided to the second signal pad P_{S2}, a digital input having a value of 1 is provided to the third signal pad P_{S3}, and a digital input having a value of 0 is provided to the fourth signal pad P_{S4}. The digital inputs cause the second phase shifter segment 110b to introduce a phase shift φ₂ between the first waveguide path 106a and the second waveguide path 106b, while the first phase shifter segment 110a does not introduce a phase shift between the first waveguide path 106a and the second waveguide path 106b. Therefore, cumulative phase shift between the first phase shifter segment 110a and the second phase shifter segment 110b is equal to φ_{B}+φ₂, giving the optical output signal a second amplitude at the wavelength λ₁. Graph 302b shows an example of curve 306 corresponding to an optical output power (shown on y-axis) of the optical output signal over a range of wavelengths (shown on x-axis).

As shown in top-view 300c of FIG. 3C, a digital input having a value of 1 is provided to the first signal pad Psi, a digital input having a value of 0 is provided to the second signal pad P_{S2}, a digital input having a value of 0 is provided to the third signal pad P_{S3}, and a digital input having a value of 0 is provided to the fourth signal pad P_{S4}. The digital inputs cause the first phase shifter segment 110a to introduce a phase shift φ₁ between the first waveguide path 106a and the second waveguide path 106b, while the second phase shifter segment 110b does not introduce a phase shift between the first waveguide path 106a and the second waveguide path 106b. Therefore, cumulative phase shift between the first phase shifter segment 110a and the second phase shifter segment 110b is equal to P_{B}+φ₁, giving the optical output signal a third amplitude at the wavelength λ₁. Graph 302c shows an example of curve 308 corresponding to an optical output power (shown on y-axis) of the optical output signal over a range of wavelengths (shown on x-axis).

As shown in top-view 300d of FIG. 3D, a digital input having a value of 1 is provided to the first signal pad Psi, a digital input having a value of 0 is provided to the second signal pad P_{S2}, a digital input having a value of 1 is provided to the third signal pad P_{S3}, and a digital input having a value of 0 is provided to the fourth signal pad P_{S4}. The digital inputs cause the first phase shifter segment 110a to introduce a phase shift φ₁ between the first waveguide path 106a and the second waveguide path 106b and the second phase shifter segment 110b to introduce a phase shift φ₂ between the first waveguide path 106a and the second waveguide path 106b. Therefore, cumulative phase shift between the first phase shifter segment 110a and the second phase shifter segment 110b is equal to φ_{B}+φ₁+φ₂, giving the optical output signal 118 a fourth amplitude at the wavelength λ₁. Graph 302d shows an example of curve 310 corresponding to an optical output power (shown on y-axis) of the optical output signal over a range of wavelengths (shown on x-axis).

FIG. 3E illustrates a graph 312 showing some embodiments of different optical output signals generated by the 2-bit optical DAC in response to the different digital input signals of FIGS. 3A-3D.

As shown in graph 312, the different phase shifts cause the different optical output to be shifted along the x-axis. The shifts cause the different optical output signals generated by different digital inputs to have different amplitudes at the wavelength ki. In some embodiments, the 2-bit optical DAC may have different amplitudes at a wavelength within the O band (e.g., between approximately 1260 nm and approximately 1360 nm, approximately 1310 nm, or the like). In some embodiments, the 2-bit optical DAC may have different amplitudes at a wavelength within the C band (e.g., between approximately 1530 nm and approximately 1565 nm, approximately 1550 nm, or the like).

FIG. 3F illustrates a graph 314 showing some embodiments of optical output powers at a given wavelength output by the 2-bit optical DAC in response to different digital input signals.

As shown in graph 314, the different phase shifts allow for the 2-bit optical DAC to generate four (4) discrete optical output powers 316a-316d. The four (4) discrete optical output powers 316a-316d respectively correspond to a different digital input signal. For example, the 2-bit optical DAC is configured to generate an optical output signal having a first optical output power 316a with a first amplitude in response to a digital signal (0, 0), the 2-bit optical DAC is configured to generate an optical output signal having a second optical output power 316b with a second amplitude in response to a digital signal (0, 1), the 2-bit optical DAC is configured to generate an optical output signal having a third optical output power 316c with a third amplitude in response to a digital signal (1, 0), the 2-bit optical DAC is configured to generate an optical output signal having a fourth optical output power 316d with a fourth amplitude in response to a digital signal (1, 1).

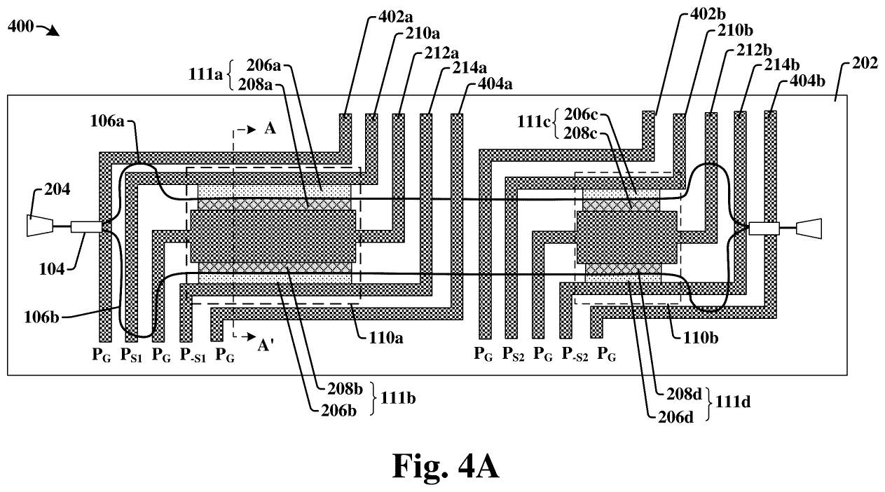

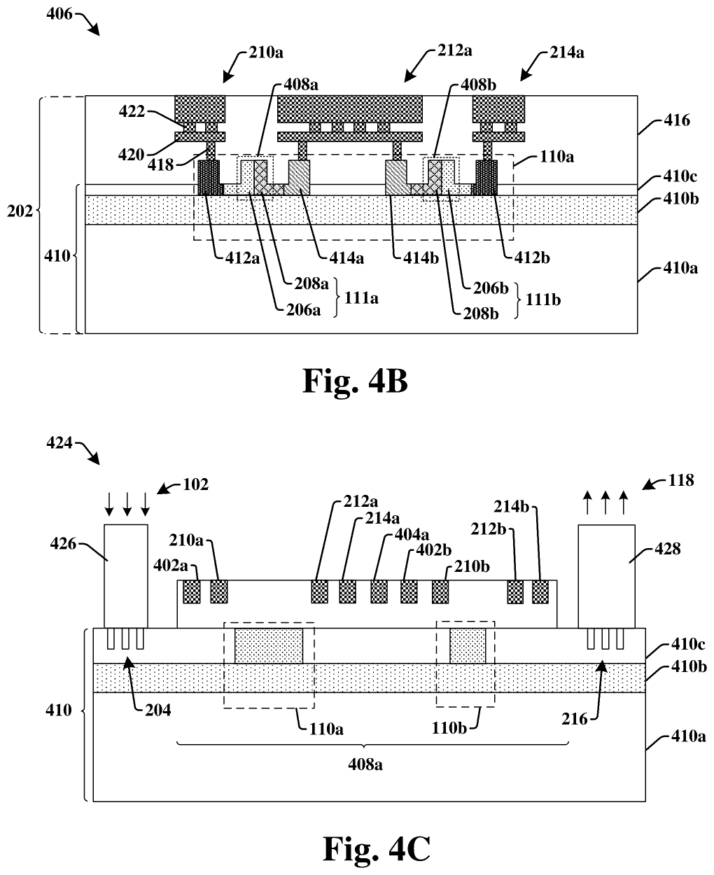

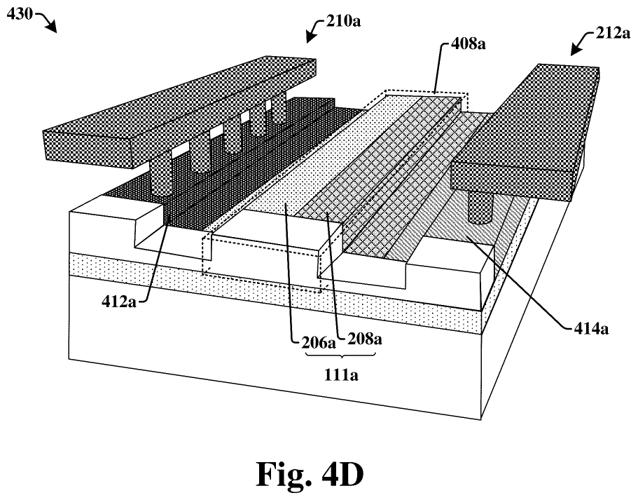

FIGS. 4A-4D illustrate some additional embodiments of an optical DAC comprising an MZM.

FIG. 4A illustrates a top-view 400 of some embodiments of an optical DAC. The optical DAC comprises an input conduit 204 disposed on and/or within a substrate 410. The input conduit 204 is coupled to a beam splitter 104 that is configured provide a first optical input signal to a first waveguide path 106a and a second optical input signal to a second waveguide path 106b via. The first waveguide path 106a extends through a first phase shifter 111a within a first phase shifter segment 110a and a third phase shifter 111c within a second phase shifter segment 110b. The second waveguide path 106b extends through a second phase shifter 111b within the first phase shifter segment 110a and a fourth phase shifter 111d within the second phase shifter segment 110b.

The first phase shifter 111a comprises a first doped region 206a contacting a second doped region 208a along a first p-n junction. The second phase shifter 111b comprises a third doped region 206b contacting a fourth doped region 208b along a second p-n junction. The third phase shifter 111c comprises a fifth doped region 206c contacting a sixth doped region 208c along a third p-n junction. The fourth phase shifter 111d comprises a seventh doped region 206d contacting an eighth doped region 208d along a fourth p-n junction.

A plurality of interconnect structures 210a-214b are coupled to phase shifter segments 110a-110b. For example, a first interconnect structure 210a is coupled to the first doped region 206a, a second interconnect structure 212a is coupled to the second doped region 208a and to the fourth doped region 208b, and a third interconnect structure 214a is coupled to the third doped region 206b. In some embodiments, one or more additional interconnect structures 402a-402b and 404a-404b may extend over the substrate 202 and be coupled to the phase shifter segments 110a-110b. The one or more additional interconnect structures are configured to allow for differential signals to be provided to one or more p-n junctions of the phase shifter segments 110a-110b. For example, in some embodiments, first interconnect structure 210a and additional interconnect structure 402a may be configured to carry complimentary signals (e.g., 210a may provide a ‘0’ and 214a may provide a ‘1’) to enable the first phase shifter segment 110a to receive a differential signal, while fourth interconnect structure 210b and additional interconnect structure 402b may be configured to carry complimentary signals (e.g., 210b may provide a ‘0’ and 214b may provide a ‘1’) to enable the second phase shifter segment 110b to receive a differential signal. Therefore, differential signals may be simultaneously input to the two arms of the MZM by five pads. Since both arms of the MZM are driven by a bias voltage, the use of differential signals may increase an extinction ratio between optical output powers corresponding to different digital signals.

It will be appreciated that the illustrated pad assignments are only exemplary pad assignments and that in other embodiments different bias voltages may be selectively applied to different pads. For example, in other embodiments (not shown) first interconnect structure 210a and additional interconnect structure 402a may carry complimentary signals (e.g., 402a may provide a ‘0’ and 210a may provide a ‘1’) to enable the first phase shifter 111a to receive a differential signal, while third interconnect structure 214a and additional interconnect structure 404a may carry complimentary signals (e.g., 404a may provide a ‘0’ and 214a may provide a ‘1’) to enable the second phase shifter 111b to receive a differential signal. In some such embodiments, the interconnect structure and the additional interconnect structure carrying complimentary signals may be coupled to a differential amplifier, which is configured to provide a differential signal (e.g., a bias voltage) to a phase shifter.

FIG. 4B illustrates a cross-sectional view 406 of some embodiments of the optical DAC taken along cross-sectional line A-A′ of FIG. 4A. As shown in cross-sectional view 406, a first waveguide 408a and a second waveguide 408b are disposed on and/or within a substrate 410. The first waveguide path (106a of FIG. 4A) is configured to extend through the first waveguide 408a and the second waveguide path (106b of FIG. 4A) is configured to extend through the second waveguide 408b. In some embodiments, the substrate 410 may comprise an SOI substrate. In such embodiments, the substrate 410 comprises a base substrate 410a separated from an active layer 410c by an insulating layer 410b. In some embodiments, the base substrate 410a may comprise or be a silicon substrate. In some embodiments, the insulating layer 410b may comprise or be an oxide (e.g., silicon oxide). In some embodiments, the active layer 410c may comprise or be silicon. In some embodiments, the first waveguide 408a and a second waveguide 408b are disposed within the active layer 410c.

In some embodiments, and the first waveguide 408a and the second waveguide 408b may respectively include a fin comprising a semiconductor material (e.g., silicon) protruding outward from an upper surface of the substrate 410. In some embodiments, the fin may form a ridge waveguide, a rib waveguide, a strip loaded waveguide, or the like. In some embodiments, at least a part of the fin may be covered by a cladding layer (not shown) comprising a material having a different (e.g., lower) index of refraction than the fin (e.g., a metal, a semiconductor, etc.).

Within the first phase shifter segment 110a, the first waveguide 408a includes the first doped region 206a and the second doped region 208a abutting one another along the first p-n junction. A first doped contact region 412a laterally abuts the first doped region 206a and a second doped contact region 414a laterally abuts the second doped region 208a. The first doped contact region 412a may comprise a same doping type (e.g., n-type) as the first doped region 206a and the second doped contact region 414a may comprise a same doping type (e.g., p-type) as the second doped region 208a.

Within the first phase shifter segment 110a, the second waveguide 408b includes the third doped region 206b and the fourth doped region 208b abutting one another along the second p-n junction. A third doped contact region 412b laterally abuts the third doped region 206b and a fourth doped contact region 414b laterally abuts the fourth doped region 208b. The third doped contact region 412b may comprise a same doping type (e.g., n-type) as the third doped region 206b and the fourth doped contact region 414b may comprise a same doping type (e.g., p-type) as the fourth doped region 208b.

An inter-level dielectric (ILD) structure 416 is disposed over the substrate 410. The ILD structure 416 surrounds one or more interconnect structures 210a-214a that are coupled to the doped contact regions 412a-414b. In some embodiments, the one or more interconnect structures 210a-214a may comprise a conductive contact 418, an interconnect wire 420, and/or an interconnect via 422. In some embodiments, the ILD structure 416 may comprise one or more of silicon dioxide, SiCOH, borophosphate silicate glass (BSG), phosphosilicate glass (PSG), borophosphosilicate glass (BPSG), fluorosilicate glass (FSG), undoped silicate glass (USG), or the like. In some embodiments, the one or more interconnect structures 210a-214a may comprise a conductive material, such as tungsten, copper, aluminum, ruthenium, tantalum, titanium, or the like.

FIG. 4C illustrates a cross-sectional view 424 of some embodiments of the optical DAC taken along cross-sectional line following the first waveguide path (e.g., 106a of FIG. 4A).

As shown in cross-sectional view 424, In some embodiments a fiber optic input channel 426 (e.g., a fiber optic waveguide) is arranged in communication with the input conduit 204. The fiber optic input channel 426 is configured to provide an optical input signal 102 to the input conduit 204. The input conduit 204 is connected to the first waveguide 408a, which extends though the first phase shifter segment 110a and the second phase shifter segment 110b. The first waveguide 408a further extends to an output conduit 216, which may be coupled to a fiber optic output channel 428 (e.g., a fiber optic waveguide) configured to receive an optical output signal 118.

FIG. 4D illustrates a three-dimensional view 430 of some embodiments of the first phase shifter 111a. As shown in three-dimensional view 430, the first waveguide 408a comprises a rib waveguide that interfaces with the first doped region 206a and the second doped region 208a of the first phase shifter 111a. In some embodiments, the rib waveguide may have a sidewall that laterally contacts sidewalls of the first doped region 206a and the second doped region 208a of the first phase shifter 111a. In some embodiments, the rib waveguide may have a same width and/or height as the first phase shifter 111a. In some embodiments, the rib waveguide and/or the first doped region 206a and the second doped region 208a may have a first doping concentration over a width of the rib waveguide and a different, second doping concentration laterally outside of the rib waveguide so as to increase internal confinement of radiation (e.g., light) within the rib waveguide and/or the first phase shifter 111a.

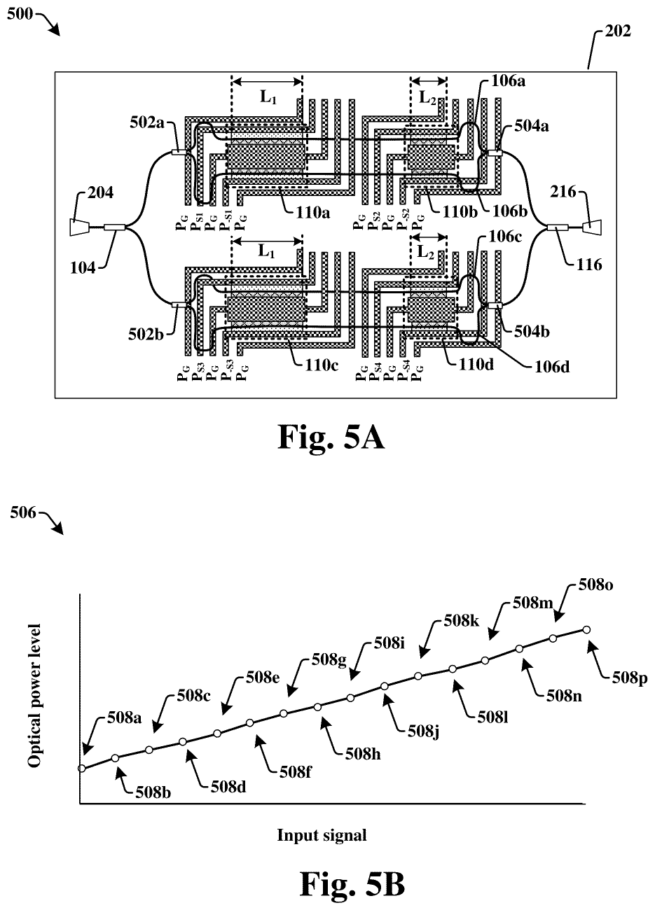

FIG. 5A illustrates a top-view of some embodiments of a 4-bit optical DAC 500 comprising an MZM.

The 4-bit optical DAC 500 comprises a beam splitter 104 configured to split an optical input signal into two optical input signals. A plurality of additional beam splitters 502a-502b are configured to split the two optical input signals into four different optical signals that are provided along different waveguide paths 106a-106d extending in parallel to one another. The four different waveguide paths 106a-106d comprise a first waveguide path 106a and a second waveguide path 106b having a different path length than the first waveguide path 106a. The first waveguide path 106a and the second waveguide path 106b extend through a first phase shifter segment 110a and a second phase shifter segment 110b. The first phase shifter segment 110a and the second phase shifter segment 110b respectively comprise signal pads P_{S1}-P_{S4} configured to receive digital inputs.

The four different waveguide paths 106a-106d further comprise a third waveguide path 106c and a fourth waveguide path 106d having a different path length than the third waveguide path 106c. The third waveguide path 106c and the fourth waveguide path 106d extend through a third phase shifter segment 110c and a fourth phase shifter segment 110d. The third phase shifter segment 110c and the fourth phase shifter segment 110d respectively comprise signal pads P_{S5}-P_{S8} configured to receive digital inputs.

The four different waveguide paths 106a-106d are configured to provide the four different optical signals to a plurality of additional beam couplers 504a-504b. The plurality of additional beam couplers 504a-504b are configured to add the four different optical signals to generate two optical output signals. The two optical output signals are further provided to a beam combiner 116 that is configured to add the two optical output signals to generate an optical output signal.

In some embodiments, the beam splitter 104 may have a coupling ratio that is approximately 1:1 (50%). In such embodiments, the beam splitter 104 is configured to split the optical input signal equally between the first optical input signal and the second optical input signal. In other embodiments, the beam splitter 104 may have a coupling ratio that is less than 50%. For example, of the beam splitter 104 may have a coupling ratio that 1:2 (e.g., about 33%). Having the beam splitter 104 with a coupling ratio of 1:2 enables phase shifter segments 110a-110b within waveguide paths 106a-106b to generate different optical output powers than phase shifter segments 110c-110d within waveguide paths 106c-106d, thereby allowing the optical DAC 500 to provide uniform differences between optical output powers. In other embodiments, the beam splitter 104 may have a coupling ratio of between approximately 0.001% and approximately 99.999% (e.g., such as 30%, 33%, 50%, 60%).

FIG. 5B illustrates a graph 506 showing some embodiments of optical output powers generated by the 4-bit optical DAC of FIG. 5A in response to different digital input signals.

As shown in graph 506, utilizing the phase shift segments 110a-110d to introduce different phase shifts allows for the 4-bit optical DAC to generate an optical output signal having sixteen (16) discrete optical output powers 508a-508p. The sixteen (16) discrete optical output powers 508a-508p respectively correspond to a different digital input signal.

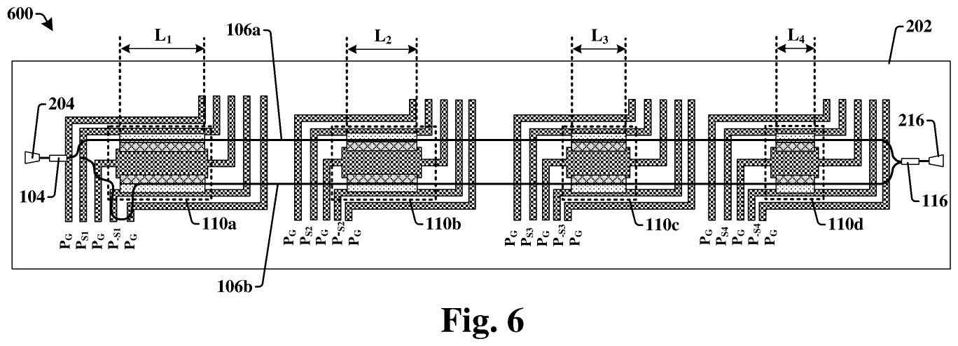

FIG. 6 illustrates a top-view of some additional embodiments of a 4-bit optical DAC 600 comprising an MZM.

The 4-bit optical DAC 600 comprises a beam splitter 104 configured to split an optical input signal into a first optical signal provided to a first waveguide path 106a and a second optical signal provided to a second waveguide path 106b having a different path length than the first waveguide path 106a. The first waveguide path 106a and the second waveguide path 106b extend through a plurality of phase shifter segments 110a-110d arranged in series with one another. In some embodiments, the plurality of phase shifter segments 110a-110d have p-n junctions extending along different lengths L₁-L₄. For example, a first phase shifter segment 110a may have a first p-n junction extending along a first length L₁, a second phase shifter segment 110b may have a second p-n junction extending along a second length L₂, a third phase shifter segment 110c may have a third p-n junction extending along a third length L₃, and a fourth phase shifter segment 110d may have a fourth p-n junction extending along a fourth length L₄.

Each of the plurality of phase shifter segments 110c-110d is configured to receive a digital input (e.g., the first phase shifter segment 110a is configured to receive a first digital input, the second phase shifter segment 110b is configured to receive a second digital input, etc.). Based upon the digital inputs, the plurality of phase shifter segments 110c-110d are configured to generate an optical output signal having 16 different and discrete optical output powers. The different lengths L₁-L₄ enable the 4-bit optical DAC 600 to generate the different optical output powers. In some embodiments, the different lengths L₁-L₄ are multiples of one another. For example, in some embodiments, a ratio of the different lengths may be approximately equal to L₁:L₂:L₃:L₄=8:4:2:1. In other embodiments, a ratio of the different lengths may be approximately equal to L₁:L₂:L₃:L₄=4:3:2:1.

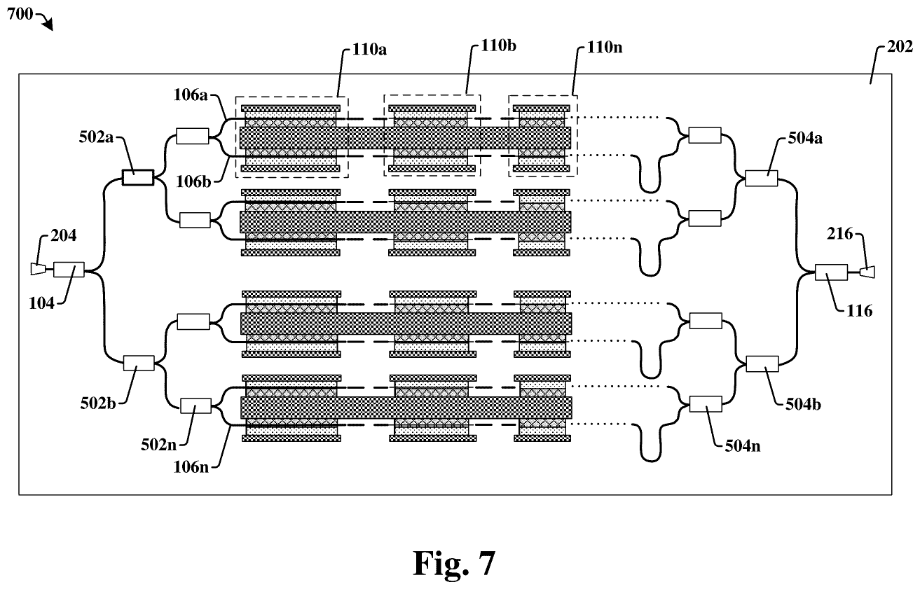

FIG. 7 illustrates a top-view of some embodiments of a disclosed n-bit optical DAC 700 comprising an MZM.

The n-bit optical DAC 700 comprises a beam splitter 104 configured to split an optical input signal into a first optical input signal and a second optical input signal. The first optical input signal and the second input optical signal are further provided to a plurality of additional optical beam splitters 502a-502n configured to split the optical input signal into n different optical signals provided to n different waveguide paths 106a-106n. A plurality of phase shifter segments 110a-110n are arranged along each of the n different waveguide paths 106a-106n. The plurality of phase shifter segments 110a-110n are respectively configured to receive a digital input (e.g., a first phase shifter segment 110a is configured to receive a first digital input, a second phase shifter segment 110b is configured to receive a second digital input, and an n^{th} phase shifter segment 110n is configured to receive an nth digital input). The plurality of phase shifter segments 110a-110n enable the n-bit optical DAC 700 to generate an optical output signal having n² different and discrete optical output powers from n different digital inputs.

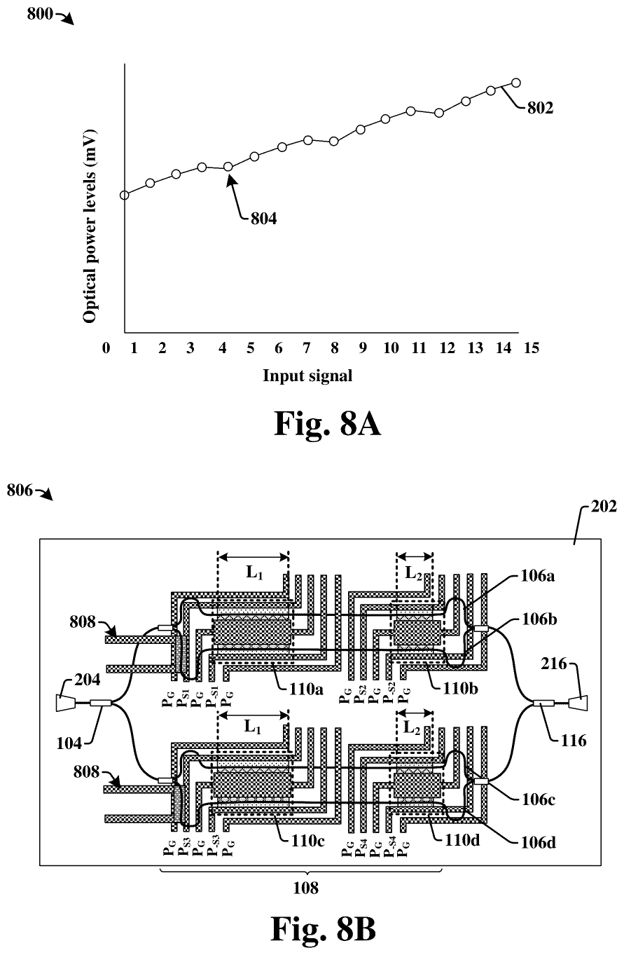

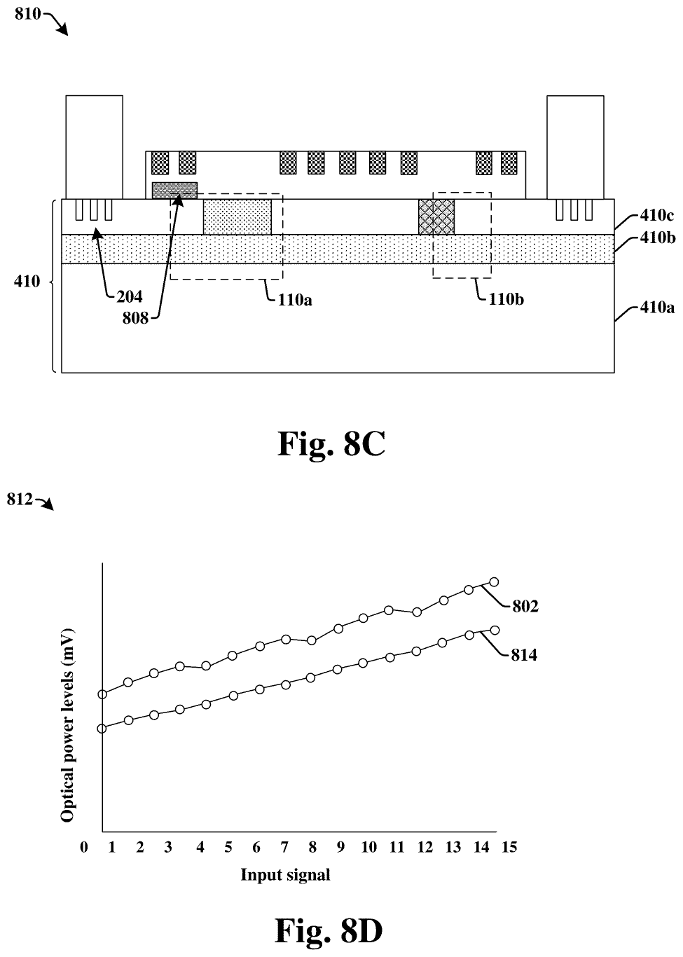

It has been appreciated that fabrication process variations can have an effect on a linearity between optical output powers of an optical output signal generated by the disclosed optical DAC. For example, FIG. 8A illustrates a graph 800 showing optical output signals corresponding to an optical DAC having an MZM with fabrication process variations. As can be seen in graph 800, points corresponding to optical output powers are shown along trend line 802. The fabrication process variations may result in non-linearities in values of the optical output powers 804 that make it difficult to differentiate different digital input signals from one another. For example, digital input signals 0-3 correspond to optical output powers that are separated by constant differences, while digital input signal 4 has an optical output power that is less than digital input signal 3. Because fabrication process variations are unpredictable, such fabrication process variations may negatively impact performance of the disclosed optical DAC.

FIG. 8B illustrate a top-view 806 of some additional embodiments of a disclosed optical DAC comprising a MZM and a temperature adjustment element configured to mitigate variations in optical output powers due to fabrication process variations.

As shown in top-view 806, the MZM 108 comprises a temperature adjustment element 808 that is configured to account for changes in the optical output signal that are due to fabrication process variations. In some embodiments, the temperature adjustment element 808 is configured to increase a temperature along one of the waveguide paths 106a-106b. In some embodiments, the temperature adjustment element 808 is configured to increase a temperature along a longer waveguide path (e.g., within an extended region of the second waveguide path 106b). In other embodiments, the temperature adjustment element 808 may comprise a cooler configured to reduce a temperature along one of the waveguide paths 106a-106b.

In some embodiments, the temperature adjustment element 808 may comprise a heater configured to generate heat. In some embodiments, the temperature adjustment element 808 may comprise a metal heater located above the waveguide. For example, cross-sectional view 810 of FIG. 8C, illustrates some embodiments of a temperature adjustment element 808 comprising a metal heater located within an ILD structure 416 over a substrate 410. As shown in cross-sectional view 810, the metal heater may be disposed vertically between the waveguide path and an overlying interconnect. In other embodiments (not shown), the temperature adjustment element 808 may comprise a silicon heater (e.g., doped silicon) arranged adjacent to the waveguide.

FIG. 8D illustrates a graph 812 showing some embodiments of optical output powers generated by the optical DAC of FIGS. 8B-8C.

Graph 812 shows a trend line 802 extending along points corresponding to optical output powers of an optical DAC not having a temperature adjustment element (e.g., a heater). Graph 812 also shows a trend line 814 extending along points corresponding to optical output powers of an optical DAC having a temperature adjustment element (e.g., a heater) that is configured to account for changes in the optical output signal that are due to fabrication process variations. As can be seen from trend line 814, the temperature adjustment element (808 of FIG. 8C) is able to mitigate the non-linearities between the optical output powers and provide for optical output powers that are at more regular differences. Therefore, the temperature adjustment element improves performance of the disclosed optical DAC.

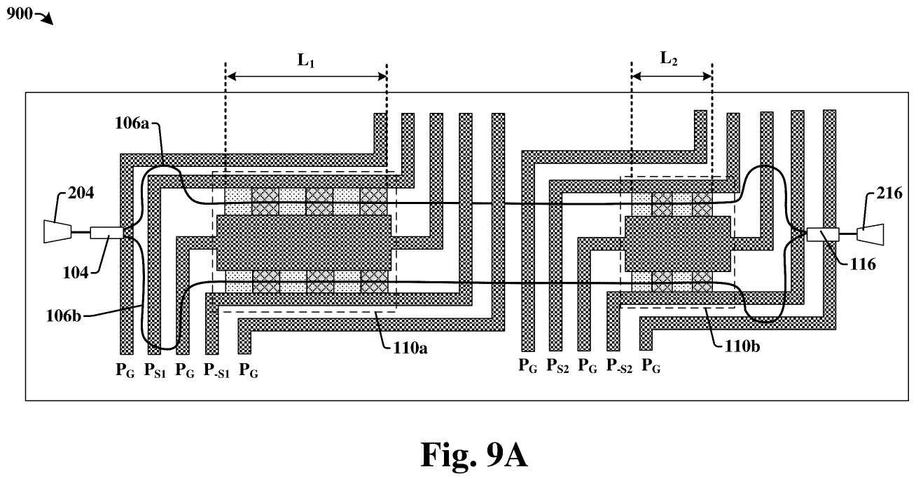

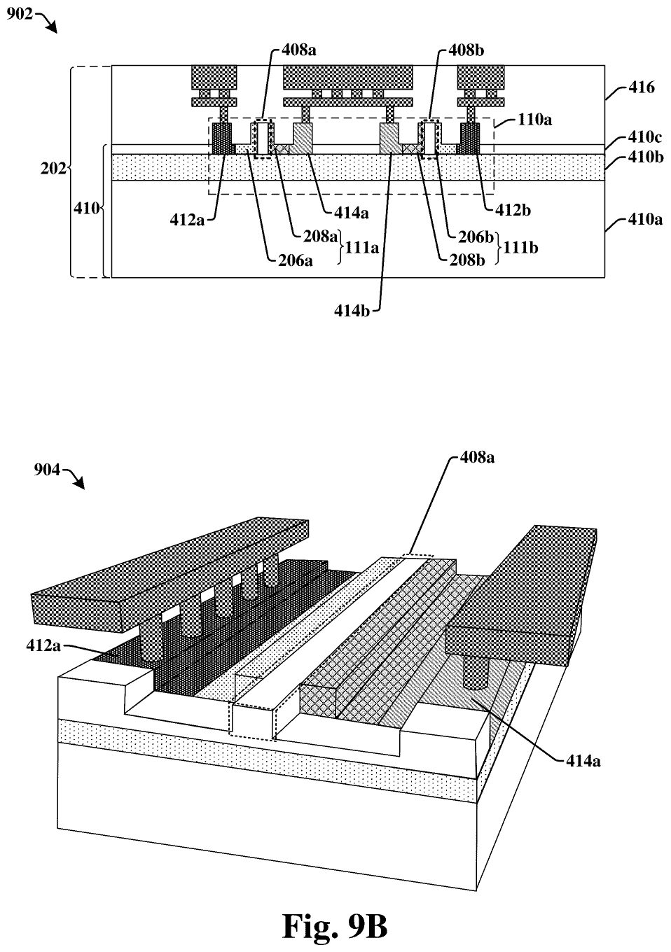

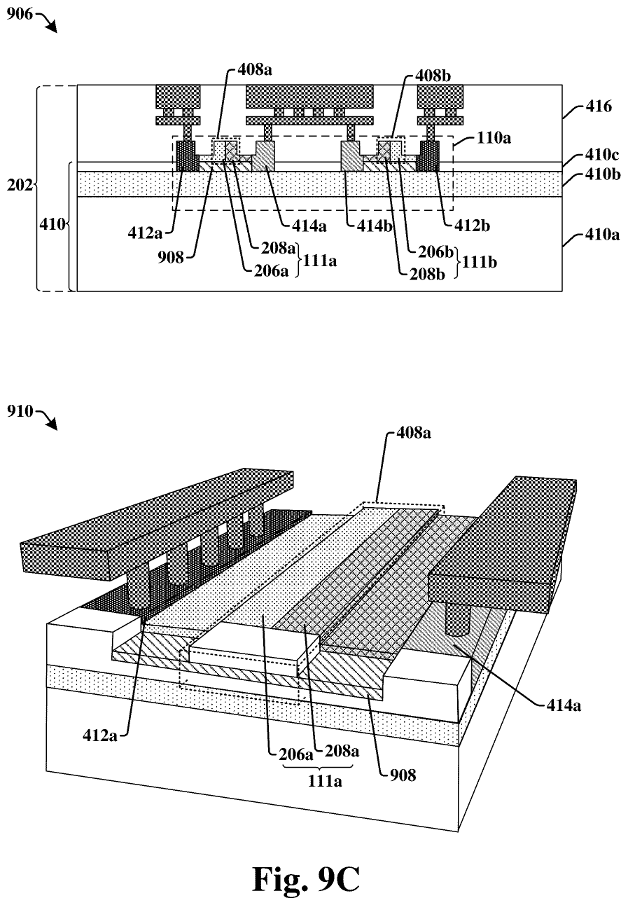

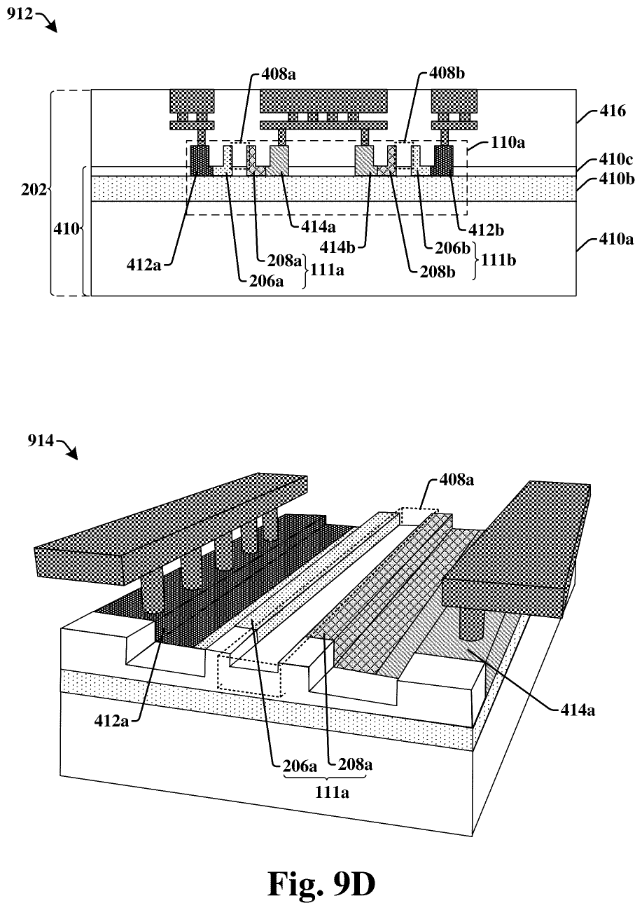

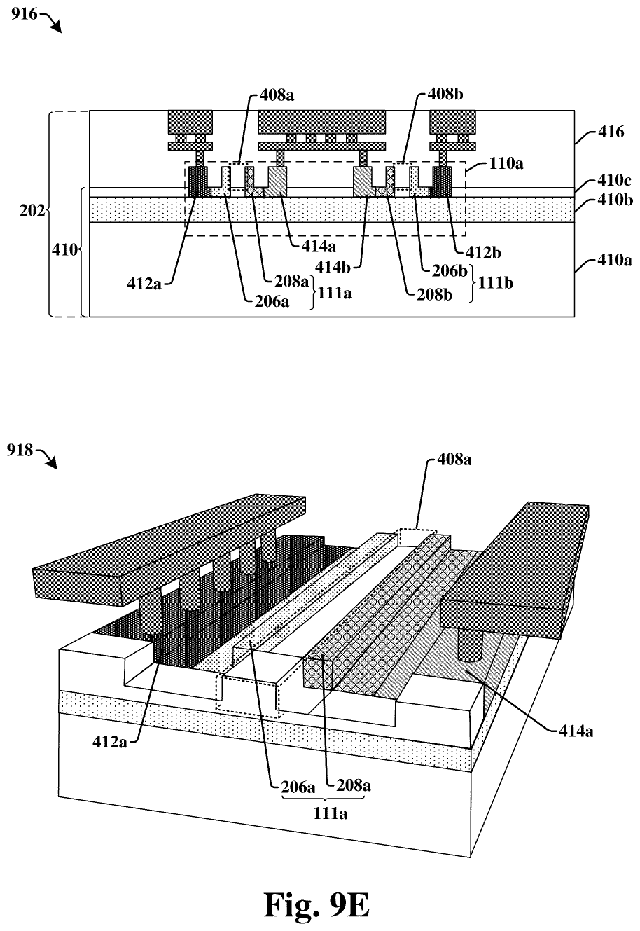

While the disclosed optical DACs illustrated in the embodiments of FIGS. 2-8D comprise phase shifters having lateral p-n junctions that extend along a rib waveguide, it will be appreciated that the disclosed optical DAC is not limited to phase shifters and/or waveguides having structures shown in the embodiments of FIGS. 2-8D. In other embodiments, the disclosed optical DACs may be implemented with different phase shifters and/or waveguide types (e.g., a buried channel waveguide, a strip-loaded waveguide, a ridge waveguide, a slot waveguide, a diffused waveguide, and/or the like). For example, FIGS. 9A-9E illustrate some additional embodiments of disclosed optical DACs comprising waveguides and/or phase shifters having alternative structures. It will be appreciated that the waveguides and/or phase shifters shown in FIGS. 9A-9E are not limiting, but rather are further examples of waveguides and/or phase shifters that may be used to implement the disclosed optical DAC.

FIG. 9A illustrates a top-view of some additional embodiments of a disclosed optical DAC 900 comprising an MZM. The optical DAC 900 comprises a first waveguide path 106a and a second waveguide path 106b respectively extending through a first phase shifter segment 110a and a second phase shifter segment 110b. The first phase shifter segment 110a comprises a plurality of p-n junctions that are arranged along a direction that is perpendicular to the first waveguide path 106a and/or the second waveguide path 106b. In some embodiments, the doped regions forming the plurality of p-n junctions within the first phase shifter segment 110a may extend over a first length L₁ and the doped regions forming the plurality of p-n junctions within the second phase shifter segment 110b may extend over a second length L₂ that is different than the first length L₁.

FIG. 9B illustrates a cross-sectional view 902 showing waveguides 408a-408b comprising alternative embodiments of rib waveguides. The waveguides 408a-408b include a first rib waveguide continuously extending between sidewalls of doped regions 206a-208a and a second rib waveguide continuously extending between sidewalls of doped regions 206b-208b. The first rib waveguide comprises sidewalls that face the sidewalls of doped regions 206a-208a. The second rib waveguide comprises sidewalls that face the sidewalls of doped regions 206b-208b. FIG. 9B also illustrates a three-dimensional view 904 corresponding to the first waveguide 408a shown in cross-sectional view 902.

FIG. 9C illustrates a cross-sectional view 906 showing waveguides 408a-408b comprising strip waveguides. The waveguides 408a-408b include a first strip waveguide and a second strip waveguide respectively disposed over a lower material 908 having a different index of refraction than the first and second strip waveguides. In some embodiments, the first and second strip waveguides may comprise a semiconductor material (e.g., silicon) and the lower material 908 may comprise a dielectric (e.g., silicon oxide). FIG. 9C also illustrates a three-dimensional view 910 corresponding to the first waveguide 408a of cross-sectional view 906.

FIG. 9D illustrates a cross-sectional view 912 showing waveguides 408a-408b comprising slot waveguides. The waveguides 408a-408b comprise a first slot waveguide continuously extending between doped regions 206a-208a and a second slot waveguide continuously extending between doped regions 206b-208b. FIG. 9D also illustrates a three-dimensional view 914 corresponding to the first waveguide 408a of cross-sectional view 912.

In some embodiments, the slot waveguides may comprise cavities between doped regions 206a-208a and between doped regions 206b-208b. In other embodiments (not shown), the slot waveguides may comprise a first material (e.g., silicon, silicon dioxide, or the like) continuously extending between doped regions 206a-208a and a second material (e.g., silicon, silicon dioxide, or the like) continuously extending between doped regions 206b-208b. In such embodiments, the first material comprises sidewalls that face sidewalls of doped regions 206a-208a and the second material comprises sidewalls that face sidewalls of doped regions 206b-208b.

In yet other embodiments, the disclosed optical DAC may comprise a mixture or combination of different types of waveguides. For example, FIG. 9E illustrates a cross-sectional view 916 showing waveguides 408a-408b comprising a first rib waveguide that interfaces with a first slot waveguide disposed between doped regions 206a-208a and a second rib waveguide that interfaces with a second slot waveguide disposed between doped regions 206b-208b. FIG. 9E also illustrates a three-dimensional view 918 corresponding to the first waveguide 408a of cross-sectional view 916.

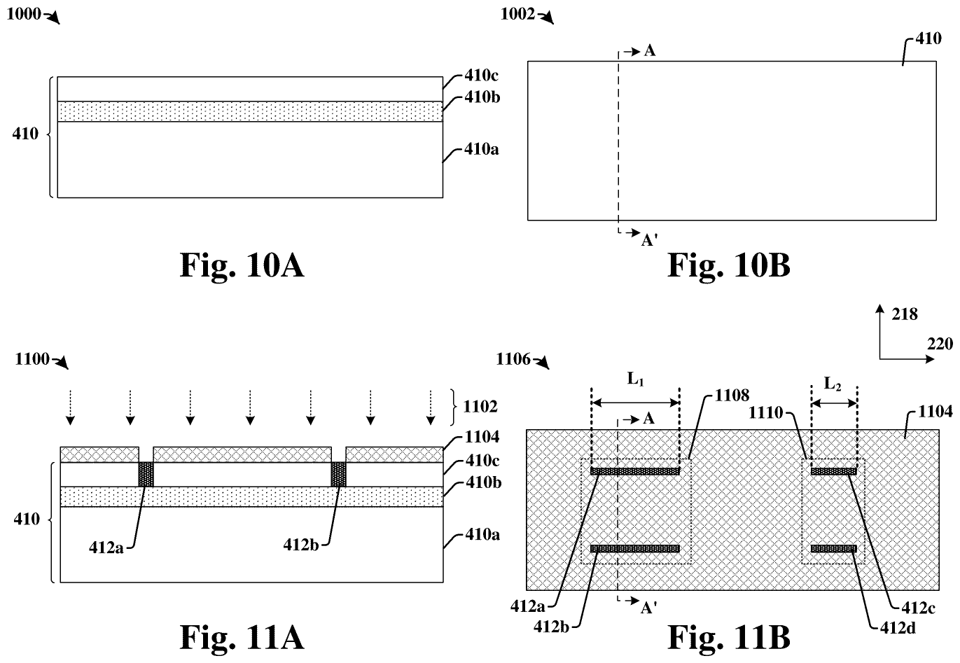

FIGS. 10A-19B illustrate some embodiments of a method of forming an integrated chip structure including an optical DAC comprising an MZM. Although FIGS. 10A-19B are described in relation to a method, it will be appreciated that the structures disclosed in the method are not limited to the method, but instead may stand alone as structures independent of the method.

As shown in cross-sectional view 1000 of FIG. 10A, a substrate 410 is provided. In various embodiments, the substrate 410 may be any type of semiconductor body (e.g., silicon, SiGe, etc.), such as a semiconductor wafer and/or one or more die on a wafer, as well as any other type of semiconductor and/or epitaxial layers, associated therewith. In some embodiments, the substrate 410 may comprise an SOI substrate having a base substrate 410a separated from an active layer 410c by an insulating layer 410b.

FIG. 10B illustrates a top-view 1002 corresponding to cross-sectional view 1000 of FIG. 10A. The cross-sectional view 1000 of FIG. 10A is taken along cross-sectional view A-A′ of the top-view 1002 of FIG. 10B.

As shown in cross-sectional view 1100 of FIG. 11A and top-view 1106 of FIG. 11B, a first plurality of doped contact regions 412a-412d are formed within the substrate 410. In some embodiments, the first plurality of doped contact regions 412a-412d are formed within the active layer 410c of the substrate 410. The first plurality of doped contact regions 412a-412d may be formed by selectively implanting a first dopant species 1102 having a first doping type into the substrate 410. In some embodiments, the first dopant species 1102 may be implanted into the substrate 410 according to a first mask 1104. In some embodiments, the first dopant species 1102 may comprise a p-type dopant, such as boron, gallium, or the like. In some embodiments, the first mask 1104 may comprise photoresist, a dielectric (e.g., silicon dioxide), or the like.

As shown in top-view 1106, the first plurality of doped contact regions 412a-412d may comprise a first pair of doped contact regions 412a-412b formed within a first phase shifter region 1108 and a second pair of doped contact regions 412c-412d formed within a second phase shifter region 1110. The first pair of doped contact regions 412a-412b are separated from one another along a first direction 218. The second pair of doped contact regions 412c-412d are separated from one another along the first direction 218. The first pair of doped contact regions 412a-412b are separated from the second pair of doped contact regions 412c-412d by non-zero distances along a second direction 220 that is perpendicular to the first direction 218. The first pair of doped contact regions 412a-412b respectively extend for a first length L₁ along the second direction 220. The second pair of doped contact regions 412c-412d extend for a second length L₂ along the second direction 220. The second length L₂ is different than (e.g., smaller than) the first length L₁. In some embodiments, the second length L₂ may be half of the first length L₁.

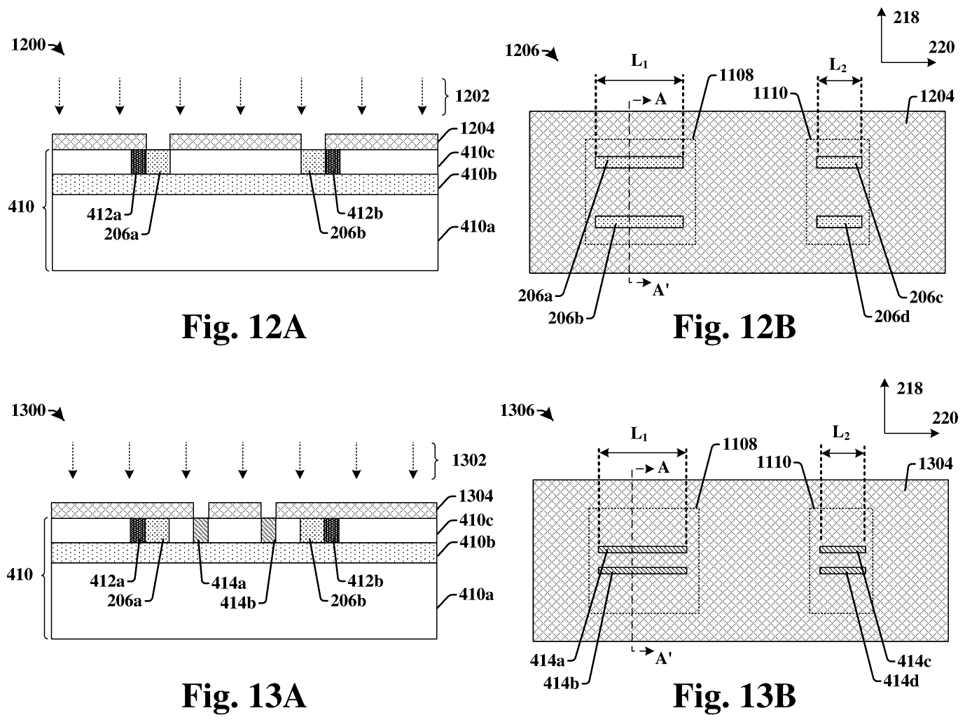

As shown in cross-sectional view 1200 of FIG. 12A and top-view 1206 of FIG. 12B, a first plurality of doped regions 206a-206d are formed within the substrate 410 (e.g., within the active layer 410c of the substrate 410). In some embodiments, the first plurality of doped regions 206a-206d are formed by selectively implanting a second dopant species 1202 having the first doping type into the substrate 410. The second dopant species 1202 may be implanted into the substrate 410 according to a second mask 1204. In some embodiments, the second dopant species 1202 may comprise a p-type dopant, such as boron, gallium, or the like. In some embodiments, the first dopant species (1102 of FIG. 11A) and the second dopant species 1202 may be a same dopant species. In some embodiments, the second mask 1204 may comprise photoresist, a dielectric (e.g., silicon dioxide), or the like.

As shown in top-view 1206, the first plurality of doped regions 206a-206d may comprise a first pair of doped regions 206a-206b formed within the first phase shifter region 1108 and a second pair of doped regions 206c-206d formed within the second phase shifter region 1110. The first pair of doped regions 206a-206b are separated from one another along the first direction 218 and extend for the first length L₁ along the second direction 220. The second pair of doped regions 206c-206d are separated from one another along the first direction 218 and extend for a second length L₂ along the second direction 220. The first pair of doped regions 206a-206b are separated from the second pair of doped regions 206c-206d by non-zero distances along the second direction 220.

As shown in cross-sectional view 1300 of FIG. 13A and top-view 1306 of FIG. 13B, a second plurality of doped contact regions 414a-414d are formed within the substrate 410 (e.g., within the active layer 410c of the substrate 410). In some embodiments, the second plurality of doped contact regions 414a-414d are formed by selectively implanting a third dopant species 1302 having a second doping type into the substrate 410. The third dopant species 1302 may be implanted into the substrate 410 according to a third mask 1304. In some embodiments, the third dopant species 1302 may be comprise an n-type dopant, such as arsenic, phosphorous, or the like.

As shown in top-view 1306, the second plurality of doped contact regions 414a-414d may comprise a third pair of doped contact regions 414a-414b formed within the first phase shifter region 1108 and a fourth pair of doped regions 414c-414d formed within the second phase shifter region 1110. The third pair of doped contact regions 414a-414b are separated from one another along the first direction 218 and extend for the first length L₁ along the second direction 220. The fourth pair of doped contact regions 414c-414d are separated from one another along the first direction 218 and extend for a second length L₂ along the second direction 220. The third pair of doped contact regions 414a-414b are separated from the fourth pair of doped contact regions 414c-414d by non-zero distances along the second direction 220.

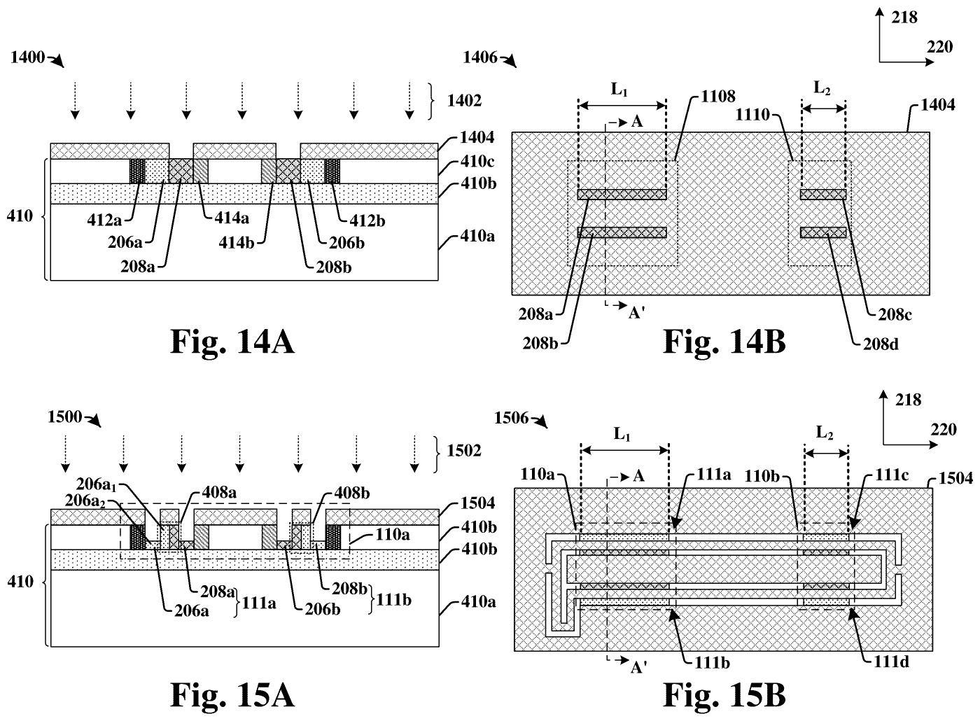

As shown in cross-sectional view 1400 of FIG. 14A and top-view 1406 of FIG. 14B, a second plurality of doped regions 208a-208d are formed within the substrate 410 (e.g., within the active layer 410c of the substrate 410). In some embodiments, the second plurality of doped regions 208a-208d are formed by selectively implanting a fourth dopant species 1402 having the second doping type into the substrate 410. In some embodiments, the fourth dopant species 1402 may be implanted into the substrate 410 according to a fourth mask 1404. In some embodiments, the fourth dopant species 1402 may be comprise n n-type dopant, such as arsenic, phosphorous, or the like. In some embodiments, the third dopant species (1302 of FIG. 13A) and the fourth dopant species 1402 may be a same dopant species.

As shown in top-view 1406, the second plurality of doped regions 208a-208d may comprise a third pair of doped regions 208a-208b formed within the first phase shifter region 1108 and a fourth pair of doped regions 208a-208b formed within the second phase shifter region 1110. The third pair of doped regions 208a-208b are separated from one another along the first direction 218 and extend for the first length L₁ along the second direction 220. The fourth pair of doped regions 208a-208b are separated from one another along the first direction 218 and extend for a second length L₂ along the second direction 220. The third pair of doped regions 208a-208b are separated from the fourth doped regions 208c-208d by non-zero distances along the second direction 220.

As shown in cross-sectional view 1500 of FIG. 15A and top-view 1506 of FIG. 15B, a part of the first plurality of doped regions 206a-206d and a part of the second plurality of doped regions 208a-208d are recessed to form recessed parts of the substrate 410 that extend along opposing sides of waveguides 408a-408b. The waveguides 408a-408b comprise a first pair of p-n junctions extending along the first length L₁ within a first phase shifter segment 110a and a second pair of p-n junctions extending along the second length L₂ within a second phase shifter segment 110b. A first p-n junction within the first phase shifter segment 110a forms a first phase shifter 111a and a second p-n junction within the first phase shifter segment 110a forms a second phase shifter 111b. A third p-n junction within the second phase shifter segment 110b forms a third phase shifter 111c and a fourth p-n junction within the second phase shifter segment 110b forms a fourth phase shifter 111d.

In some embodiments, the parts of the first plurality of doped regions 206a-206d and the second plurality of doped regions 208a-208d are recessed by selectively exposing the substrate to a fifth etchant 1502 according to a fifth mask 1504. In some embodiments, the fifth etchant 1502 may comprise a dry etchant (e.g., having a fluorine chemistry, a chlorine chemistry, or the like). In some embodiments, the fifth mask 1504 may comprise photoresist, a hard mask (e.g., silicon oxy-nitride), or the like. In some embodiments, segments of the doped regions within the waveguides 408a-408b may have different doping concentrations than segments of the doped regions outside of the waveguides 408a-408b. For example, first doped region 206a may have a first region 206a₁ that has a different doping type than a second region 206a₂ so as to increase internal refraction within first waveguide 408a.

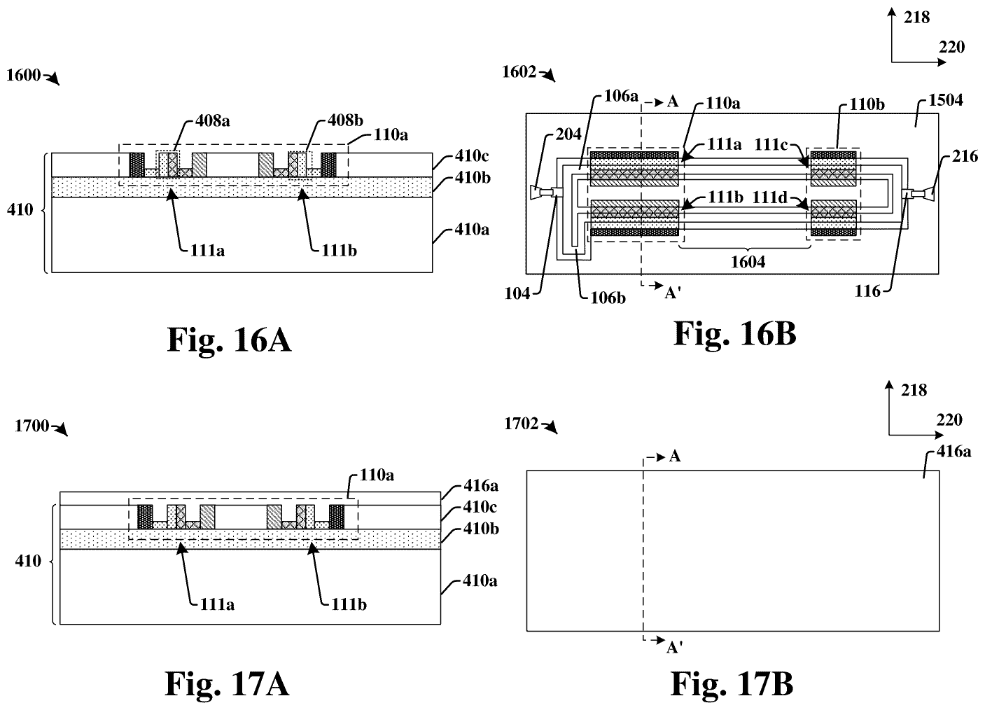

As shown in cross-sectional view 1600 of FIG. 16A and top-view 1602 of FIG. 16B, the fifth mask (e.g., 1504 of FIG. 15A) is removed. In some embodiments, the fifth mask may be removed by an etching process, an ashing process, or the like. The waveguides 408a-408b comprise a first waveguide 408a that extends along a first waveguide path 106a and a second waveguide 408b that extends along a second waveguide path 106b. The first waveguide path 106a has a different path length (e.g., a smaller path length) than second waveguide path 106b. The first waveguide path 106a extends through the first phase shifter 111a and the third phase shifter 111c. The second waveguide path 106b extends through the second phase shifter 111b and the fourth phase shifter 111d. In some embodiments, the waveguides 408a-408b comprise a non-doped region 1604 that is laterally between the first phase shifter segment 110a and the second phase shifter segment 110b along the second direction 220.

In some embodiments, a cladding layer (not shown) may be formed over the waveguides 408a-408b after removing the fifth mask (e.g., 1502 of FIG. 15A). The cladding layer may increase internal reflection to improve performance of the waveguides 408a-408b. In various embodiments, the cladding layer may comprise a metal, a dielectric, or the like.

As shown in cross-sectional view 1700 of FIG. 17A and top-view 1702 of FIG. 17B, a first inter-level dielectric (ILD) layer 416a is formed over the substrate 410. In some embodiments, the first ILD layer 416a may be formed by one or more deposition processes (e.g., a PVD process, a CVD process, a PE-CVD process, a high-density ICP deposition, a LP-CVD, or the like). In some embodiments, the first ILD layer 416a may comprise one or more of silicon dioxide, SiCOH, BSG, PSG, BPSG, FSG, USG, or the like.

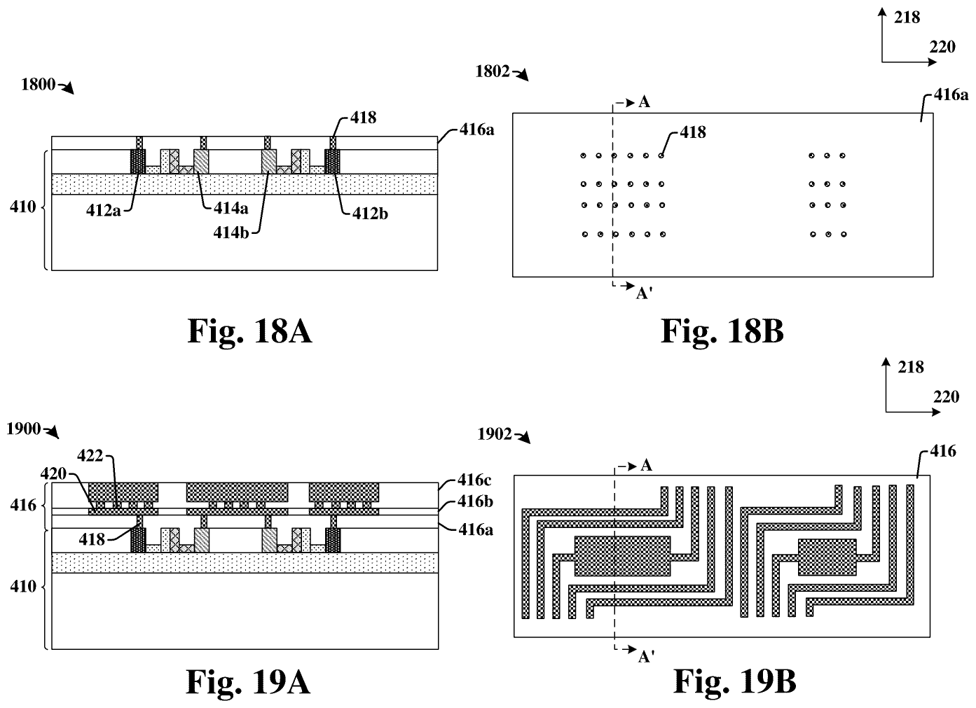

As shown in cross-sectional view 1800 of FIG. 18A and top-view 1802 of FIG. 18B, a plurality of conductive contacts 418 are formed within the first ILD layer 416a. The plurality of conductive contacts 418 are formed to extend from a top surface of the first ILD layer 416a to the first plurality of doped contact regions 412a-412d and the second plurality of doped contact regions 414a-414d. In some embodiments, the plurality of conductive contacts 418 may be formed using a damascene process (e.g., a single damascene process). The damascene process is performed by etching the first ILD layer 416a to form contact holes and filling the contact holes with a conductive material. In some embodiments, the conductive material (e.g., tungsten, copper, aluminum, or the like) may be formed using a deposition process and/or a plating process (e.g., electroplating, electro-less plating, etc.).

As shown in cross-sectional view 1900 of FIG. 19A and top-view 1902 of FIG. 19B, a plurality interconnects are formed within additional ILD layers 416b-416c formed over the first ILD layer 416a. In some embodiments, the plurality of interconnects may comprise an interconnect wire 420 and/or an interconnect via 422. In some embodiments, the plurality of interconnects may be formed using a damascene process (e.g., a single damascene process or a dual damascene process). The damascene process is performed by forming a dielectric layer over the substrate 410, etching the dielectric layer to form a via hole and/or a trench, and filling the via hole and/or the trench with a conductive material. In some embodiments, the conductive material (e.g., tungsten, copper, aluminum, or the like) may be formed using a deposition process and/or a plating process (e.g., electroplating, electro-less plating, etc.).

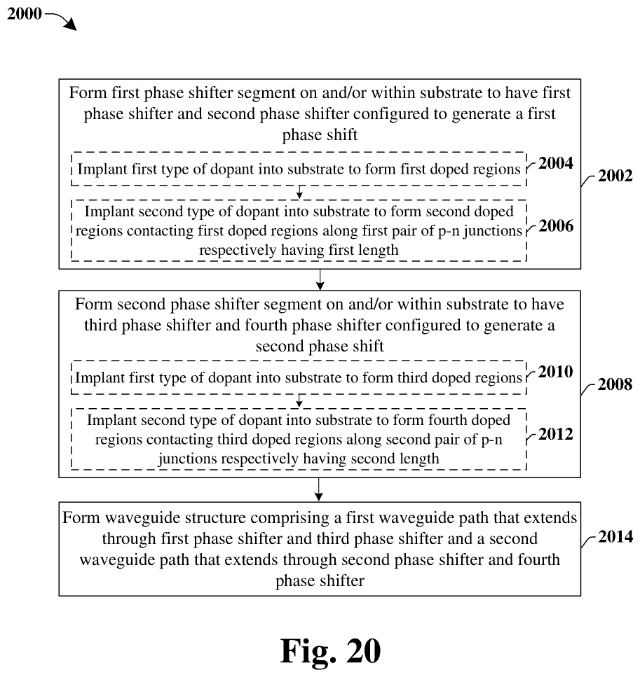

FIG. 20 illustrates a flow diagram of some embodiments of a method 2000 of an integrated chip structure including an optical DAC comprising an MZM.

While the disclosed methods (e.g., methods 2000 and 2100) are illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases

At act 2002, a first phase shifter segment is formed on and/or within a substrate to have a first phase shifter and a second phase shifter configured to generate a first phase shift. In some embodiments, the first phase shifter segment may be formed according to acts 2004-2006.

At act 2004, a first type of dopant (e.g., n-type) is implanted into the substrate to form first doped regions.

At act 2006, a second type of dopant (e.g., p-type) is implanted into the substrate to form second doped regions that contact the first doped regions along a first pair of p-n junctions respectively having a first length.

At act 2008, a second phase shifter segment is formed on and/or within the substrate to have a third phase shifter and a fourth phase shifter configured to generate a second phase shift. In some embodiments, the second phase shifter segment may be formed according to acts 2010-2012.

At act 2010, a first type of dopant (e.g., n-type) is implanted into the substrate to form third doped regions.

At act 2012, a second type of dopant (e.g., p-type) is implanted into the substrate to form fourth doped regions that contact the third doped regions along a second pair of p-n junctions respectively having a second length.

At act 2014, a waveguide structure is formed to comprise a first waveguide path that extends through the first phase shifter and the third phase shifter and a second waveguide path that extends through the second phase shifter and the fourth phase shifter.

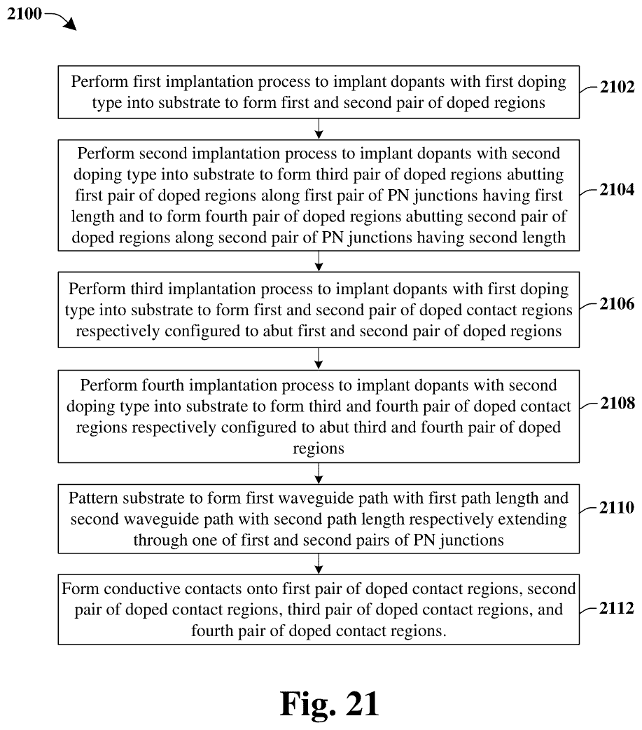

FIG. 21 illustrates a flow diagram of some additional embodiments of a method 2100 of forming an integrated chip structure including an optical DAC comprising an MZM.

At act 2102, a first implantation process is performed to implant dopants with a first doping type into a substrate to form a first pair of doped regions and a second pair of doped regions. FIGS. 12A-12B illustrate some embodiments corresponding to act 2102.

At act 2104, a second implantation process is performed to implant dopants with a second doping type into the substrate to form a third pair of doped regions and a fourth pair of doped regions. The third pair of doped regions abut the first pair of doped regions along a first pair of PN junctions having a first length. The fourth pair of doped regions abut the second pair of doped regions along a second pair of PN junctions having a second length. FIGS. 14A-14B illustrate some embodiments corresponding to act 2104.

At act 2106, a third implantation process is performed to implant dopants with the first doping type into the substrate to form a first pair of doped contact regions and a second pair of doped contact regions. The first pair of doped contact regions are configured to abut the first pair of doped regions and the second pair of doped contact regions are configured to abut the second pair of doped regions. FIGS. 11A-11B illustrate some embodiments corresponding to act 2106.

At act 2108, a fourth implantation process is performed to implant dopants with the second doping type into the substrate to form a third pair of doped contact regions and a fourth pair of doped contact regions. The third pair of doped contact regions are configured to abut the third pair of doped regions and the fourth pair of doped contact regions are configured to abut the fourth pair of doped regions. FIGS. 13A-13B illustrate some embodiments corresponding to act 2108.

At act 2110, the substrate is patterned to form a first waveguide path with a first path length and a second waveguide path with a second path length. The first waveguide path and the second waveguide path respectively extend through one of the first and second pair of PN junctions. FIGS. 15A-15B and FIGS. 16A-16B illustrate some embodiments corresponding to act 2110.

At act 2112, conductive contacts are formed onto the first pair of doped contact regions, the second pair of doped contact regions, the third pair of doped contact regions, and the fourth pair of doped contact regions. FIGS. 17A-17B and FIGS. 18A-18B illustrate some embodiments corresponding to act 2112.

Accordingly, the present disclosure relates to an optical digital-to-analog converter (DAC), comprising a Mach-Zehnder modulator (MZM), which is configured to modulate an optical input signal based upon a digital signal to generate an analog optical output signal.

In some embodiments, the present disclosure relates to an optical digital-to-analog converter (DAC). The optical DAC includes a first waveguide path configured to receive a first optical signal; a second waveguide path configured to receive a second optical signal; a first phase shifter segment interfacing with the first waveguide path and the second waveguide path, the first phase shifter segment being configured to selectively generate a first phase shift between the first optical signal and the second optical signal in response to a first digital input; a second phase shifter segment interfacing with the first waveguide path and the second waveguide path, the second phase shifter segment being configured to selectively generate a second phase shift between the first optical signal and the second optical signal in response to a second digital input; and the first digital input and the second digital input corresponding to different bits of a digital signal. In some embodiments, the optical DAC further includes a beam combiner disposed downstream of the second phase shifter segment and configured to combine the first optical signal and the second optical signal to generate an optical output signal having a plurality of different optical output powers corresponding to different values the digital signal. In some embodiments, the first phase shifter segment includes a first doped region having a first type doping and a second doped region having a second doping type. In some embodiments, the first phase shifter segment includes a first p-n junction extending along the first waveguide path for a first length and the second phase shifter segment includes a second p-n junction extending along the first waveguide path for a second length. In some embodiments, the first waveguide path has a smaller path length than the second waveguide path. In some embodiments, the optical DAC further includes a heater configured to heat a part of the second waveguide path to a higher temperature than the first waveguide path. In some embodiments, the second phase shifter segment is located downstream of the first phase shifter segment. In some embodiments, the optical DAC further includes a third phase shifter segment in communication with the first waveguide path and the second waveguide path and disposed downstream of the second phase shifter segment, the third phase shifter segment being configured to selectively generate a third phase shift between the first optical signal and the second optical signal in response to a third digital input. In some embodiments, the first phase shifter segment includes a first p-n junction extending along the first waveguide path for a first length, the second phase shifter segment comprises a second p-n junction extending along the first waveguide path for a second length, and the third phase shifter segment comprises a third p-n junction extending along the first waveguide path for a third length; a ratio of the first length to the second length to the third length is approximately equal to 3:2:1. In some embodiments, the optical DAC further includes a fourth phase shifter segment in communication with the first waveguide path and the second waveguide path and disposed downstream of the third phase shifter segment, the fourth phase shifter segment being configured to selectively generate a fourth phase shift between the first optical signal and the second optical signal in response to a fourth digital input. In some embodiments, the optical DAC further includes a third waveguide path configured to receive a third optical signal; a fourth waveguide path configured to receive a fourth optical signal; a third phase shifter segment in communication with the third waveguide path and the fourth waveguide path, the third phase shifter segment being configured to selectively generate a third phase shift between the third optical signal and the fourth optical signal in response to a third digital input; and a fourth phase shifter segment in communication with the third waveguide path and the fourth waveguide path, the fourth phase shifter segment being configured to selectively generate a fourth phase shift between the third optical signal and the fourth optical signal in response to a fourth digital input. In some embodiments, the first waveguide path and the second waveguide path are arranged in parallel to the third waveguide path and the fourth waveguide path.

In other embodiments, the present disclosure relates to an optical digital-to-analog converter (DAC). The optical DAC includes a first phase shifter segment having a first plurality of doped regions extending over a first length, the first plurality of doped regions forming a first p-n junction and a second p-n junction; a second phase shifter segment having a second plurality of doped regions extending over a second length that is different than the first length, the second plurality of doped regions forming a third p-n junction and a fourth p-n junction; a first waveguide path having a first path length and extending through the first p-n junction and the third p-n junction; and a second waveguide path having a second path length and extending through the second p-n junction and the fourth p-n junction, the second path length being larger than the first path length. In some embodiments, the optical DAC further includes a first signal pad coupled to the first p-n junction by a first interconnect structure; a second signal pad coupled to the second p-n junction by a second interconnect structure; a third signal pad coupled to the third p-n junction by a third interconnect structure; and a fourth signal pad coupled to the fourth p-n junction by a fourth interconnect structure. In some embodiments, the optical DAC further includes a waveguide disposed over a substrate and extending along the first waveguide path and through the first p-n junction and the third p-n junction. In some embodiments, the waveguide includes a semiconductor material having a non-doped region between the first p-n junction and the third p-n junction. In some embodiments, the first p-n junction is separated from the second p-n junction along a first direction and wherein the first phase shifter segment is separated from the second phase shifter segment along a second direction that is perpendicular to the first direction. In some embodiments, a ratio of the first length to the second length is approximately equal to 2:1.

In yet other embodiments, the present disclosure relates to a method of forming an optical digital to analog converter (DAC). The method includes performing a first implantation process to implant dopants with a first doping type into a substrate to form a first pair of doped regions and a second pair of doped regions; performing a second implantation process to implant dopants with a second doping type into the substrate to form a third pair of doped regions and a fourth pair of doped regions, the third pair of doped regions abutting the first pair of doped regions along a first pair of PN junctions respectively having a first length and the fourth pair of doped regions abutting the second pair of doped regions along a second pair of PN junctions respectively having a second length; and patterning the substrate to form a first waveguide path with a first path length and a second waveguide path with a second path length, the first waveguide path and the second waveguide path respectively extending through one of the first pair of PN junctions and one of the second pair of PN junctions. In some embodiments, the first length is approximately twice as long as the second length.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1-20. (canceled)

21. An integrated chip structure, comprising:
a semiconductor material disposed over an insulating material, wherein the semiconductor material comprises a first fin and a second fin extending outward from an upper surface of the semiconductor material;
a first modulation region disposed within the first fin and comprising a first p-n junction having a first length extending along the first fin;
a second modulation region disposed within the first fin and comprising a second p-n junction having a second length extending along the first fin, the first modulation region being separated from the second modulation region by a first non-zero distance;
a third modulation region disposed within the second fin and comprising a third p-n junction having a third length extending along the second fin; and
a fourth modulation region disposed within the second fin and comprising a fourth p-n junction having a fourth length extending along the second fin, the fourth modulation region being separated from the third modulation region by a second non-zero distance.

22. The integrated chip structure of claim 21,
wherein the first p-n junction comprises a first p-type region laterally abutting a first n-type region along a first interface extending between a top and a bottom of the first fin; and
wherein the third p-n junction comprises a second p-type region laterally abutting a second n-type region along a second interface extending between a top and a bottom of the second fin.

23. The integrated chip structure of claim 21,
wherein the first modulation region comprises a first doped region having a first doping type and a second doped region having a second doping type; and
wherein the third modulation region comprises a third doped region having the first doping type and a fourth doped region having the second doping type.

24. The integrated chip structure of claim 23, further comprising:
a first interconnect coupled to the first doped region;
a second interconnect coupled to the second doped region and the fourth doped region; and
a third interconnect coupled to the third doped region.

25. The integrated chip structure of claim 24, wherein the first interconnect continuously extends past opposing sides of the first doped region along a direction that extends along a long axis of the first doped region in a top-view.

26. The integrated chip structure of claim 24, wherein the second interconnect has a larger width over the first modulation region than the first interconnect in a top-view.

27. The integrated chip structure of claim 24, wherein the first fin and the second fin comprise silicon.

28. An integrated chip structure, comprising:
a substrate comprising a first optical signal path having a first path length and a second optical signal path having a second path length that is different than the first path length;
a first phase shifter interfacing with the first optical signal path along a first length in a top-view;
a second phase shifter interfacing with the second optical signal path along a second length in the top-view, the second length being substantially equal to the first length;
a third phase shifter interfacing with the first optical signal path along a third length that is different than the first length in the top-view; and
a fourth phase shifter interfacing with the second optical signal path along a fourth length that is substantially equal to the third length in the top-view.

29. The integrated chip structure of claim 28, wherein the first phase shifter comprises a first p-n junction within the first optical signal path, the second phase shifter comprises a second p-n junction within the second optical signal path, the third phase shifter comprises a third p-n junction within the first optical signal path, and the fourth phase shifter comprises a fourth p-n junction within the second optical signal path.

30. The integrated chip structure of claim 29, further comprising:
a first pair of signal interconnects arranged within an inter-level dielectric (ILD) structure over the substrate, the first pair of signal interconnects being coupled to the first p-n junction and the second p-n junction; and
a second pair of signal interconnects arranged within the ILD structure and being coupled to the third p-n junction and the fourth p-n junction.

31. The integrated chip structure of claim 30, further comprising:
a first ground interconnect arranged within the ILD structure and being coupled both the first p-n junction and the second p-n junction; and
a second ground interconnect arranged within the ILD structure and being coupled to both the third p-n junction and the fourth p-n junction.

32. The integrated chip structure of claim 29, further comprising:
a temperature adjustment element configured to vary a temperature along the first optical signal path or the second optical signal path.

33. An integrated chip structure, comprising:
a first optical signal path having a first path length and extending through a first plurality of separate phase shifters respectively having different lengths;
a second optical signal path having a second path length and extending through a second plurality of separate phase shifters respectively having different lengths;
a beam splitter connected to first ends of the first optical signal path and the second optical signal path; and
a beam coupler connected to second ends of the first optical signal path and the second optical signal path.

34. The integrated chip structure of claim 33, further comprising:
a first plurality of interconnects respectively coupled to one of the first plurality of separate phase shifters; and
a second plurality of interconnects respectively coupled to one of the second plurality of separate phase shifters.

35. The integrated chip structure of claim 34, wherein the first optical signal path extends past opposing edges of one or more of the first plurality of interconnects in a top-view.

36. The integrated chip structure of claim 34, further comprising:
a third interconnect coupled to one of the first plurality of separate phase shifters and to one of the second plurality of separate phase shifters.

37. The integrated chip structure of claim 33, wherein the first plurality of separate phase shifters comprise a first phase shifter having a first length, a second phase shifter having a second length that is approximately twice the first length, and a third phase shifter having a third length that is approximately twice the second length.

38. The integrated chip structure of claim 33, further comprising:
a third optical signal path having a third path length and extending through a third plurality of separate phase shifters respectively having different lengths;
a fourth optical signal path having a fourth path length and extending through a fourth plurality of separate phase shifters respectively having different lengths;
a second beam splitter connected to first ends of the third optical signal path and the fourth optical signal path;
a second beam coupler connected to second ends of the third optical signal path and the fourth optical signal path;
a third beam splitter connected to inputs of the beam splitter and the second beam splitter; and
a third beam coupler connected to outputs of the beam coupler and the second beam coupler.

39. The integrated chip structure of claim 33, wherein the first optical signal path comprises a waveguide structure including a semiconductor material.

40. The integrated chip structure of claim 39, wherein the first plurality of separate phase shifters include doped regions within the waveguide structure, the doped regions respectively including a p-type doped segment abutting an n-type doped segment.
